(19) United States
(12) Patent Application Publication
(10) Pub. No.: US 2025/0098215 A1
(43) Pub. Date: Mar. 20, 2025

(54) SEMICONDUCTOR DEVICE WITH GATE CONTACT OVER AN ACTIVE REGION

(71) Applicant: INTERNATIONAL BUSINESS MACHINES CORPORATION, Armonk, NY (US)

(72) Inventors: Tao Li, Slingerlands, NY (US); Ruilong Xie, Niskayuna, NY (US); Albert M. Chu, Nashua, NH (US); Nicolas Jean Loubet, Guilderland, NY (US)

(21) Appl. No.: 18/370,611

(22) Filed: Oct. 30, 2023

(51) Int. Cl. H01L 29/417; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017; H10D 84/017; H10D 84/0179; H10D 84/038; H10D 84/85

(57) ABSTRACT

A semiconductor device is provided. The semiconductor device includes an active region, a first gate electrode, a second gate electrode having a height that is less than a height of the first gate electrode, and a gate contact formed on the first gate electrode and overlapping with the active region.

### BACKGROUND

The present disclosure relates to fabrication methods and resulting structures for semiconductor devices. More specifically, the present disclosure relates to fabrication methods and resulting structures for semiconductor devices including a gate contact formed over an active region of the semiconductor device.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased.

### SUMMARY

Embodiments of the present disclosure relate to a semiconductor device. The semiconductor device includes an active region, a first gate electrode, a second gate electrode having a height that is less than a height of the first gate electrode, and a gate contact formed on the first gate electrode and overlapping with the active region. Embodiments of the present disclosure relate to a method of manufacturing a semiconductor device.

The method includes forming an active region; forming a first gate electrode; forming a second gate electrode having a height that is less than a height of the first gate electrode; and forming a gate contact on the first gate electrode and overlapping with the active region.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a partial cross-sectional view of a semiconductor device at an intermediate stage of the fabrication process and taken along the X line of FIG. 1D, according to embodiments.

FIG. 1B is a partial cross-sectional view of the semiconductor device at an intermediate stage of the fabrication process and taken along the Y1 line of FIG. 1D, according to embodiments.

FIG. 1C is a partial cross-sectional view of the semiconductor device at an intermediate stage of the fabrication process and taken along the Y2 line of FIG. 1D, according to embodiments.

FIG. 1D is a simplified top view of the semiconductor device shown in FIGS. 1A-1C, according to embodiments.

FIG. 2A is a partial cross-sectional view of the semiconductor device of FIG. 1A at a subsequent stage of the fabrication process and taken along the X line of FIG. 1D, according to embodiments.

FIG. 2B is a partial cross-sectional view of the semiconductor device of FIG. 1B at a subsequent stage of the fabrication process and taken along the Y1 line of FIG. 1D, according to embodiments.

FIG. 2C is a partial cross-sectional view of the semiconductor device of FIG. 1C at a subsequent stage of the fabrication process and taken along the Y2 line of FIG. 1D, according to embodiments.

FIG. 3A is a partial cross-sectional view of the semiconductor device of FIG. 2A at a subsequent stage of the fabrication process and taken along the X line of FIG. 3D, according to embodiments.

FIG. 3B is a partial cross-sectional view of the semiconductor device of FIG. 2B at a subsequent stage of the fabrication process and taken along the Y1 line of FIG. 3D, according to embodiments.

FIG. 3C is a partial cross-sectional view of the semiconductor device of FIG. 2C at a subsequent stage of the fabrication process and taken along the Y2 line of FIG. 3D, according to embodiments.

FIG. 3D is a simplified top view of the semiconductor device shown in FIGS. 3A-3C showing locations of a dummy gate contact, according to embodiments.

FIG. 4A is a partial cross-sectional view of the semiconductor device of FIG. 3A at a subsequent stage of the fabrication process and taken along the X line of FIG. 3D, according to embodiments.

FIG. 4B is a partial cross-sectional view of the semiconductor device of FIG. 3B at a subsequent stage of the fabrication process and taken along the Y1 line of FIG. 3D, according to embodiments.

FIG. 5A is a partial cross-sectional view of the semiconductor device of FIG. 4A at a subsequent stage of the fabrication process and taken along the X line of FIG. 3D, according to embodiments.

FIG. 5B is a partial cross-sectional view of the semiconductor device of FIG. 4B at a subsequent stage of the fabrication process and taken along the Y1 line of FIG. 3D, according to embodiments.

FIG. 5C is a partial cross-sectional view of the semiconductor device of FIG. 4C at a subsequent stage of the fabrication process and taken along the Y2 line of FIG. 3D, according to embodiments.

FIG. 6A is a partial cross-sectional view of the semiconductor device of FIG. 5A at a subsequent stage of the fabrication process and taken along the X line of FIG. 6D, according to embodiments.

FIG. 6B is a partial cross-sectional view of the semiconductor device of FIG. 5B at a subsequent stage of the fabrication process and taken along the Y1 line of FIG. 6D, according to embodiments.

FIG. 6C is a partial cross-sectional view of the semiconductor device of FIG. 5C at a subsequent stage of the fabrication process and taken along the Y2 line of FIG. 6D, according to embodiments.

FIG. 6D is a simplified top view of the semiconductor device shown in FIGS. 6A-6C showing locations of source/drain contacts, according to embodiments.

FIG. 7A is a partial cross-sectional view of the semiconductor device of FIG. 6A at a subsequent stage of the fabrication process and taken along the X line of FIG. 6D, according to embodiments.

FIG. 7B is a partial cross-sectional view of the semiconductor device of FIG. 6B at a subsequent stage of the fabrication process and taken along the Y1 line of FIG. 6D, according to embodiments.

FIG. 7C is a partial cross-sectional view of the semiconductor device of FIG. 6C at a subsequent stage of the fabrication process and taken along the Y2 line of FIG. 6D, according to embodiments.

FIG. 8A is a partial cross-sectional view of the semiconductor device of FIG. 7A at a subsequent stage of the fabrication process and taken along the X line of FIG. 6D, according to embodiments.

FIG. 8B is a partial cross-sectional view of the semiconductor device of FIG. 7B at a subsequent stage of the fabrication process and taken along the Y1 line of FIG. 6D, according to embodiments.

FIG. 8C is a partial cross-sectional view of the semiconductor device of FIG. 7C at a subsequent stage of the fabrication process and taken along the Y2 line of FIG. 6D, according to embodiments.

FIG. 9A is a partial cross-sectional view of the semiconductor device of FIG. 8A at a subsequent stage of the fabrication process and taken along the X line of FIG. 6D, according to embodiments.

FIG. 9B is a partial cross-sectional view of the semiconductor device of FIG. 8B at a subsequent stage of the fabrication process and taken along the Y1 line of FIG. 6D, according to embodiments.

FIG. 9C is a partial cross-sectional view of the semiconductor device of FIG. 8C at a subsequent stage of the fabrication process and taken along the Y2 line of FIG. 6D, according to embodiments.

FIG. 10A is a partial cross-sectional view of the semiconductor device of FIG. 9A at a subsequent stage of the fabrication process and taken along the X line of FIG. 10C, according to embodiments.

FIG. 10B is a partial cross-sectional view of the semiconductor device of FIG. 9B at a subsequent stage of the fabrication process and taken along the Y1 line of FIG. 10C, according to embodiments.

FIG. 10C is a simplified top view of the semiconductor device shown in FIGS. 10A-10B showing locations where the dummy gate contacts have been removed, according to embodiments.

FIG. 11A is a partial cross-sectional view of the semiconductor device of FIG. 10A at a subsequent stage of the fabrication process and taken along the X line of FIG. 11D, according to embodiments.

FIG. 11B is a partial cross-sectional view of the semiconductor device of FIG. 10B at a subsequent stage of the fabrication process and taken along the Y1 line of FIG. 11D, according to embodiments.

FIG. 11C is a partial cross-sectional view of the semiconductor device of FIG. 9C at a subsequent stage of the fabrication process and taken along the Y2 line of FIG. 11D, according to embodiments.

FIG. 11D is a simplified top view of the semiconductor device shown in FIGS. 11A-11C showing locations additional contact patterning, according to embodiments.

FIG. 12A is a partial cross-sectional view of the semiconductor device of FIG. 11A at a subsequent stage of the fabrication process and taken along the X line of FIG. 11D, according to embodiments.

FIG. 12B is a partial cross-sectional view of the semiconductor device of FIG. 11B at a subsequent stage of the fabrication process and taken along the Y1 line of FIG. 11D, according to embodiments.

FIG. 12C is a partial cross-sectional view of the semiconductor device of FIG. 11C at a subsequent stage of the fabrication process and taken along the Y2 line of FIG. 11D, according to embodiments.

### DETAILED DESCRIPTION

The present disclosure describes semiconductor devices including a gate contact formed over an active region of the semiconductor device, and methods of manufacturing the semiconductor devices. In particular, the present disclosure describes certain embodiments including a stacked nanosheet structure, and a gate contact that is formed over the active region of the device, where the gate contact also overlaps with channel regions. In general, a channel of the semiconductor device is an area through which charge carriers, electrons or holes, flow from the source to the drain. The conductivity of the channel is a function of the potential applied across the gate and source terminals. The gate contact region includes a first raised gate region under the gate contact, and a second raised gate region next to first raised gate region that is not directly under the gate contact. In certain embodiments, the gate region also includes a recessed gate region covered by a recessed gate cavity interlayer dielectric (ILD) layer. The first raised gate region has a first height that is greater than a second height of the second raised gate region. The recessed gate region has a third height that is less than the heights of both the first and second raised gate regions.

Having the gate contact over the active region (or gate contact over the active region (CBoA)) may be beneficial for the middle of line (MOL) to enable flexible placement of various other metal contacts, such as the source/drain contacts. In related semiconductor structures, the gate contact may be in a location so as to not overlap with the active region when viewed in plan view, and in these examples the gate contact may be located over the gate electrode but between adjacent active regions (i.e., as opposed to overlapping the active region). However, when the gate contact (CB) is located such that it overlaps with the active region (RX), the gate contact might be very close to one or more of the source/drain contacts (CA), and this has the potential to cause electrical shorting between the gate contact and the source/drain contacts. Also, with the trend toward structures with smaller critical dimensions, patterning the gate contact to overlap with the active region becomes more difficult because of the potential for misalignment and electrical shorting. However, in the present embodiments, due to the fact that the gate contact is formed over the raised gate and over the active region, this allows increased flexibility with regard to being able to form other contacts in different areas (i.e., because these areas are not occupied by the gate contact). Also, in the present embodiments, even though the gate contact may appear close to the source/drain contacts in plan view, because the gate contact is at a higher level in the thickness direction of the semiconductor device relative to the source/drain contacts, the potential for electrical shorting may be reduced or eliminated.

Because of the continuing trend toward the overall size and the smaller dimensions of the various individual structures in such semiconductor devices, it may be desirable to increase the flexibility with regard to where certain metal contacts (e.g., a gate contact) are placed.

The flowcharts and cross-sectional diagrams in the Figures illustrate methods of manufacturing semiconductor devices according to various embodiments. In some alternative implementations, the manufacturing steps may occur in a different order than that is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions.

The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

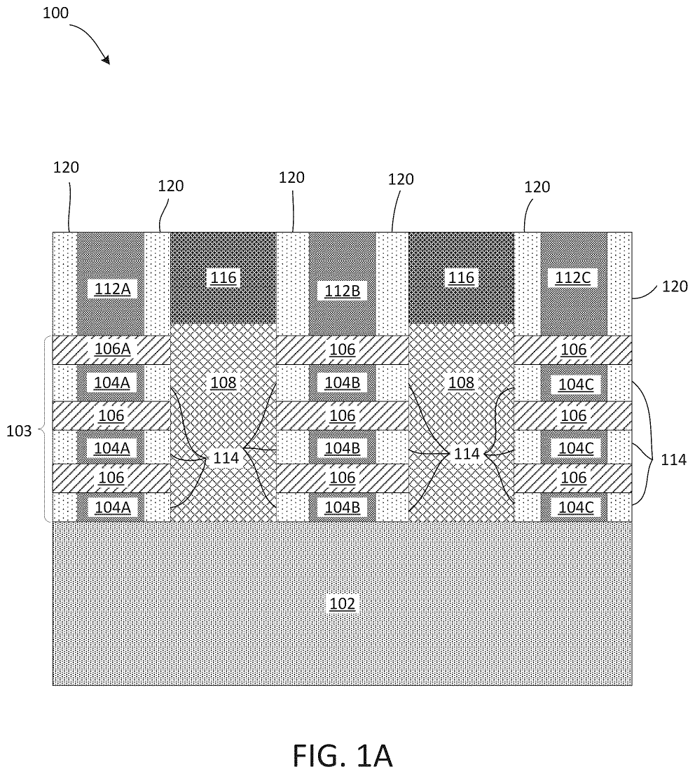

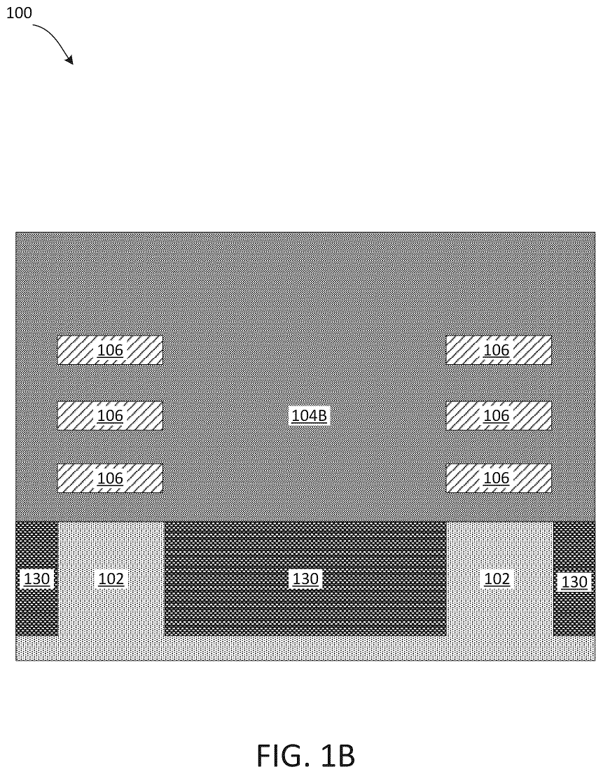

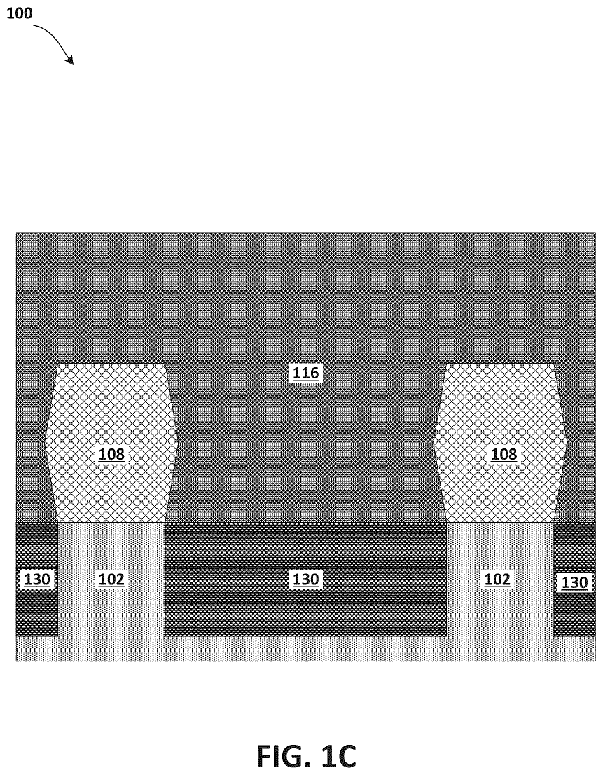

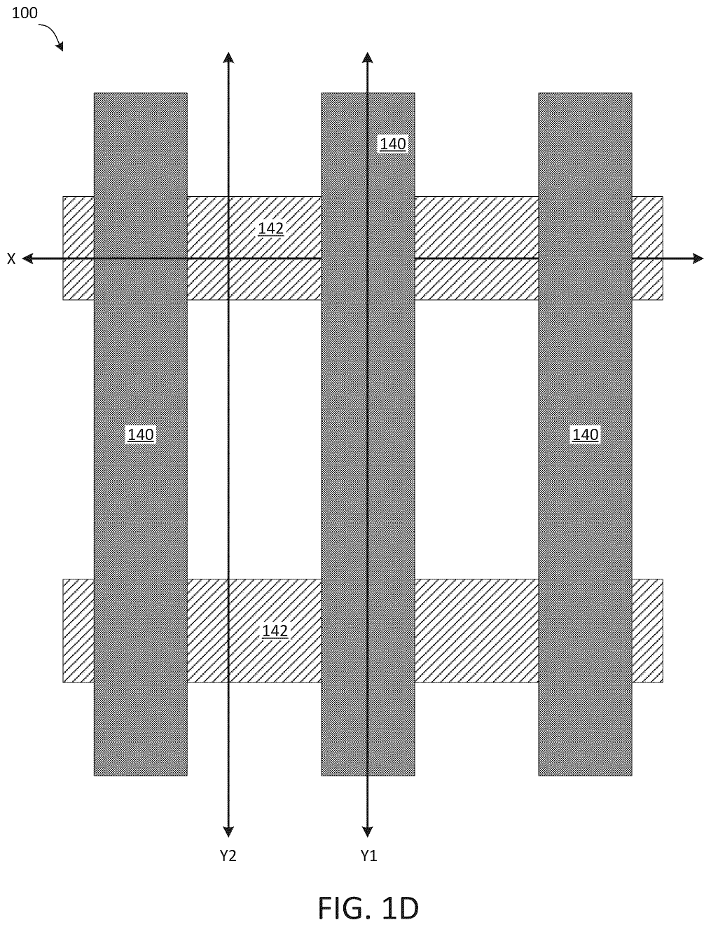

Referring now to the drawings in which like numerals represent the same or similar elements and initially to FIG. 1D, this figure is a simplified top-down (or plan) view of the semiconductor device 100, and shows the general locations of the active regions 142 (sometimes abbreviated as RX) and gate regions 140 (sometimes abbreviated as PC) of the semiconductor device 100.

Referring now to FIG. 1A, this figure is a partial cross-sectional view of a semiconductor device at an intermediate stage of the fabrication process and taken along the X line of FIG. 1D, according to embodiments. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. It should be appreciated that the substrate 102 may be comprised of any other suitable material(s) than those listed above.

Referring again to FIG. 1A, the semiconductor device 100 includes a nanosheet stack 103. The nanosheet stack 103 includes alternating layers of a semiconductor layer 106 and a gate electrode 104 that includes a work function metal (WFM). It should be appreciated that FIG. 1A shows an example where three different gate electrodes 104A, 104B and 104C are shown, and they are more generally referred to as gate electrodes 104. Although the structure shown in FIG. 1A is shown at a stage in the manufacturing process after the nanosheet stack 103 has already been formed (for the sake of simplicity), one example process of forming this stacked structure is described below. In this example, the nanosheet stack 103 is formed on the substrate 102. The nanosheet stack 103 initially includes a sacrificial layer (not shown), followed by the formation of a semiconductor layer 106. In an example, the sacrificial layer is composed of silicon-germanium (e.g., SiGe35, or more generally, where the Ge ranges from about 15-35%). Next, the first (or bottommost) semiconductor layer 106 is formed on an upper surface of the first one of the sacrificial layers. In an example, the semiconductor layer 106 is composed of silicon. Several additional layers of the sacrificial layer and the semiconductor layer 106 are alternately formed. It should be appreciated that any suitable number of alternating layers of sacrificial layers and semiconductor layers 106 may be formed.

In certain embodiments, the sacrificial layers have a vertical thickness ranging, for example, from approximately 3 nm to approximately 20 nm. In certain embodiments, the semiconductor layers 106 have a vertical thickness ranging, for example, from approximately 3 nanometers (nm) to approximately 10 nm. Although the range of 3-20 nm is cited as an example range of thickness, other thicknesses of these layers may be used. In certain embodiments, certain of the sacrificial layers and/or the semiconductor layers 106 may have different thicknesses relative to one another. Therefore, multiple epitaxial growth processes can be performed to form the sacrificial layers and the semiconductor layers 106.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers.

In certain embodiments, a dummy gate (or dummy polycrystalline (PC) layer) is formed. The dummy gate (not shown) may be formed by any suitable deposition technique known to one of skill in the art. In one example, the dummy gate is formed by depositing a thin SiO₂ dummy gate oxide layer (not shown), followed by depositing a layer of amorphous silicon (a-Si) as the dummy gate. The dummy gate may be composed of polycrystalline silicon (poly silicon), amorphous silicon, and/or an oxide, such as, SiO₂. Gate patterning may be performed by first patterning a gate hardmask (not shown) and then using the patterned gate hardmask to etch the dummy gates. After the dummy gate is formed, a spacer material is conformally deposited, forming the gate electrode spacer layers 120. After that, the stacked nanosheets at the source/drain regions which are not protected by gate hardmask and spacers are recessed in a horizontal direction, followed by inner spacer 114 formation. A selective etching process using, for example, a boron-based chemistry or a chlorine-based chemistry may be used, which selectively recesses the exposed portions of the sacrificial layers without significantly attacking the surrounding materials. Then, the inner spacers 114 are formed in the indents created by the removal of the portions of the sacrificial layers. An isotropic etching process may be performed to clean up the edges of the inner spacers 114.

A gate cut patterning process is performed (not shown) to etch away the dummy gate in a gate cut region, followed by filling the gate cut region with dielectric material. Then, the dummy gate is selectively removed, followed by removal of (or release of) the SiGe material of the sacrificial layers.

After the material of the sacrificial layers has been released, a high-x metal gate (HKMG) dielectric layer (not shown for the sake of simplicity) and a gate electrode 104 including a work function metal (WFM) are formed in the spaces created by the removal of the SiGe material of the sacrificial layers. In certain embodiments, the forming of the gate electrode 104 includes forming a continuous layer of gate dielectric material and a gate electrode material inside the gate opening. The continuous layer of gate dielectric material can include silicon oxide, or a dielectric material having a dielectric constant greater than 4.0 (such dielectric materials can be referred to as a high-x metal gate dielectric material). Illustrative examples of high-x gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The HKMG dielectric layer dielectric material can further include dopants such as lanthanum (La), aluminum (Al) and/or magnesium (Mg). The continuous layer of the high-x metal gate can be formed utilizing a deposition process such as, for example, ALD, CVD, PECVD, or PVD.

Referring back to FIG. 1A, the gate electrodes 104 may include an NFET work function metal (WFM) material or a PFET WFM material, which is deposited in the spaces created by the previous removal of the sacrificial layers in the nanosheet stack 103. The different WFM layers form the overall gate electrode 104 structures. The layer of WFM can be used to set a threshold voltage of the FET to a desired value. In some embodiments, the layer of WFM can be selected to effectuate an n-type threshold voltage shift. “N-type threshold voltage shift” as used herein means a shift in the effective work-function of the work-function metal-containing material towards a conduction band of silicon in a silicon-containing material. In solid-state physics, the work function is the minimum thermodynamic work (i.e., energy) needed to remove an electron from a solid to a point in the vacuum immediately outside the solid surface. Also, this energy (work function) is a measure of how firmly a particular metal holds its electrons. In general, the conduction band is the range of permissible energy values which an electron in a solid material can have that allows the electron to dissociate from a particular atom and become a free charge carrier in the material. In one embodiment, the work function of the n-type work function metal ranges from approximately 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the layer of WFM can be selected to effectuate a p-type threshold voltage shift. In one embodiment, the work function of the p-type work function metal ranges from approximately 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. In general, the valence band is the range of permissible energy values that are the highest energies an electron can have and still be associated with a particular atom of a solid material. Examples of such materials that can effectuate a p-type threshold voltage shift include, but are not limited to, titanium nitride, and tantalum carbide, hafnium carbide, and combinations thereof. The layers of WFM are conformal layers which can be formed by a conformal deposition process such as, for example, ALD, CVD or PECVD. The layer of WFM layer can have a thickness in the range of approximately 1 nm to 20 nm, although other thicknesses above or below this range may be used as desired for a particular application.

As also shown in FIG. 1A, source/drain epitaxial layers 108 are formed between the different nanosheet stacks 103, and are formed generally to the same or similar overall height as the nanosheet stack 103. Also, a first interlayer dielectric (ILD) layer 116 is formed on the source/drain epitaxial layers 108. An additional gate electrode material layer 112 is formed on top of the topmost semiconductor layer 106 in each of the nanosheet stacks 103, and the additional gate electrode material layer 112 may be considered to be part of the overall gate electrode 104 structure, and is indicated with a different number merely to distinguish this portion of the gate electrode 104 from the lower portions thereof in the nanosheet stack 103. As shown in FIG. 1A, gate electrode spacer layers 120 are formed on the sides of the additional gate electrode material layer 112, and are also between the additional gate electrode material layer 112 and the first ILD layer 116. In certain embodiments, an optional material removal process, such as chemical mechanical planarization (CMP) may be performed to planarize the upper surface of the overall semiconductor device 100.

Referring now to FIG. 1B, this figure is a partial cross-sectional view of the semiconductor device at an intermediate stage of the fabrication process and taken along the Y1 line of FIG. 1D, according to embodiments. As shown in FIG. 1B, shallow trench isolation (STI) regions 130 are formed in the substrate between adjacent nanosheet stacks 103. In general, shallow trench isolation is an integrated circuit feature which prevents electric current leakage between adjacent semiconductor device components. STI is generally used on CMOS process technology nodes of 250 nanometers and smaller. STI regions 130 are created early during the semiconductor device fabrication process before transistors are formed. The key steps of the STI process involve etching a pattern of trenches in the silicon, depositing one or more dielectric materials (such as silicon dioxide) to fill the trenches, and removing the excess dielectric using a technique such as chemical-mechanical planarization. The gate electrode 104 is shown to surround the semiconductor layers 106.

Referring now to FIG. 1C, this figure is a partial cross-sectional view of the semiconductor device at an intermediate stage of the fabrication process and taken along the Y2 line of FIG. 1D, according to embodiments. As shown in FIG. 1C, the source/drain epitaxial layers 108 are formed on the substrate 102 at positions other than where the STI regions 130 are located.

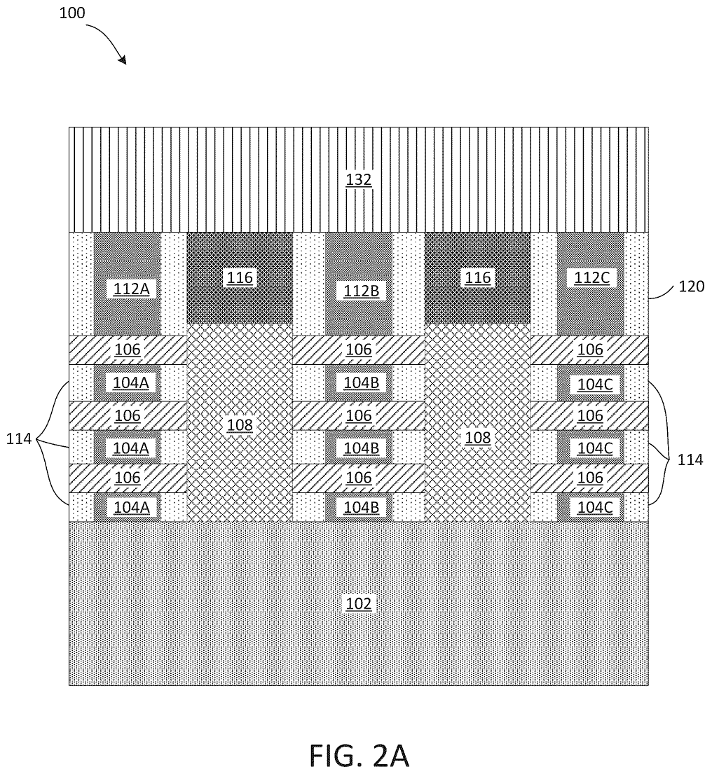

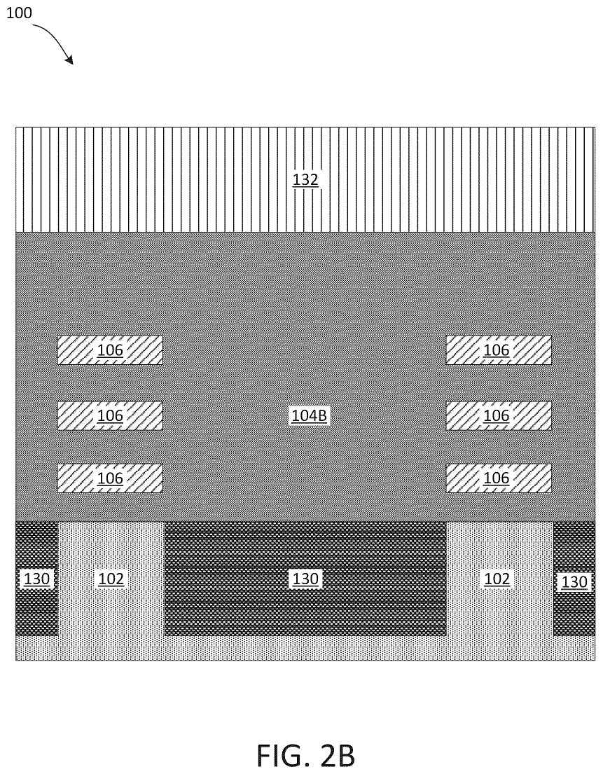

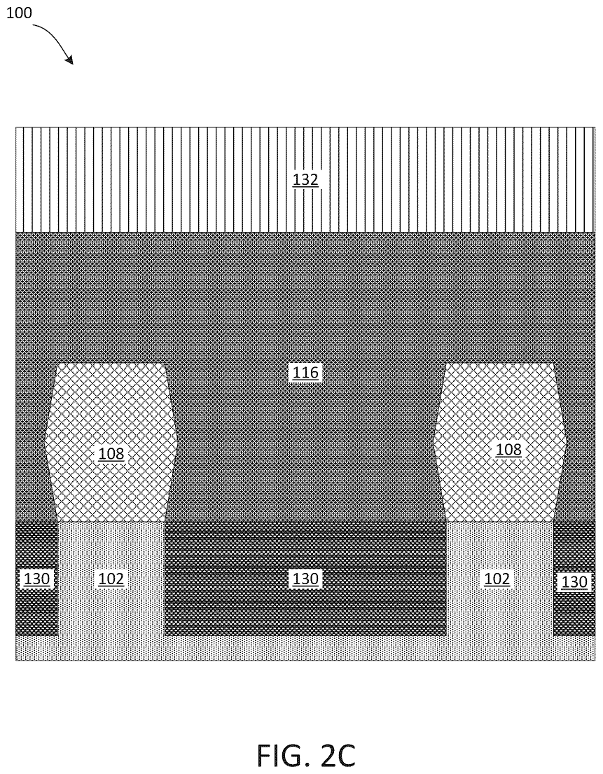

Referring now to FIG. 2A, this figure is a partial cross-sectional view of the semiconductor device of FIG. 1A at a subsequent stage of the fabrication process and taken along the X line of FIG. 1D, according to embodiments. As shown in FIG. 2A, a dummy gate contact layer 132 (or sacrificial gate contact layer) is formed on the first ILD layer 116, on the additional gate electrode material layers 112A, 112B and 112C, and on the gate electrode spacer layers 120. The dummy gate contact layer 132 may include one or more of SiC, SiOC, AlOₓ, etc. It should be appreciated that in certain embodiments, the material of the dummy gate contact layer 132 has etching selectivity relative to the first ILD layer 116. As will be described in further detail below, the dummy gate contact layer 132 will be patterned to form the dummy gate contact, and then eventually removed to allow for subsequent formation of the gate contacts 190 (also referred to as CB).

Referring now to FIG. 2B, this figure is a partial cross-sectional view of the semiconductor device of FIG. 1B at a subsequent stage of the fabrication process and taken along the Y1 line of FIG. 1D, according to embodiments. FIG. 2B also shows the formation of the dummy gate contact layer 132.

Referring now to FIG. 2C, this figure is a partial cross-sectional view of the semiconductor device of FIG. 1C at a subsequent stage of the fabrication process and taken along the Y2 line of FIG. 1D, according to embodiments. FIG. 2C also shows the formation of the dummy gate contact layer 132.

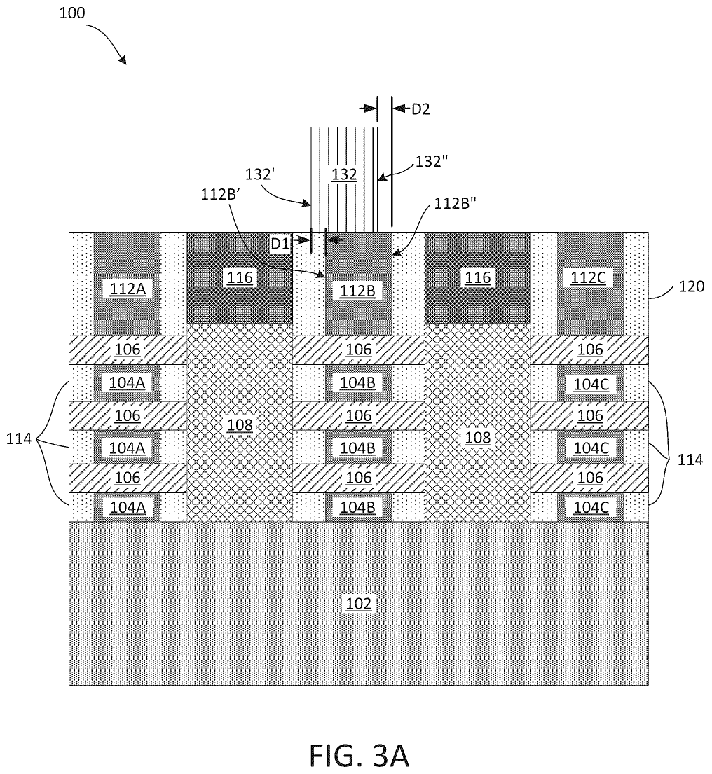

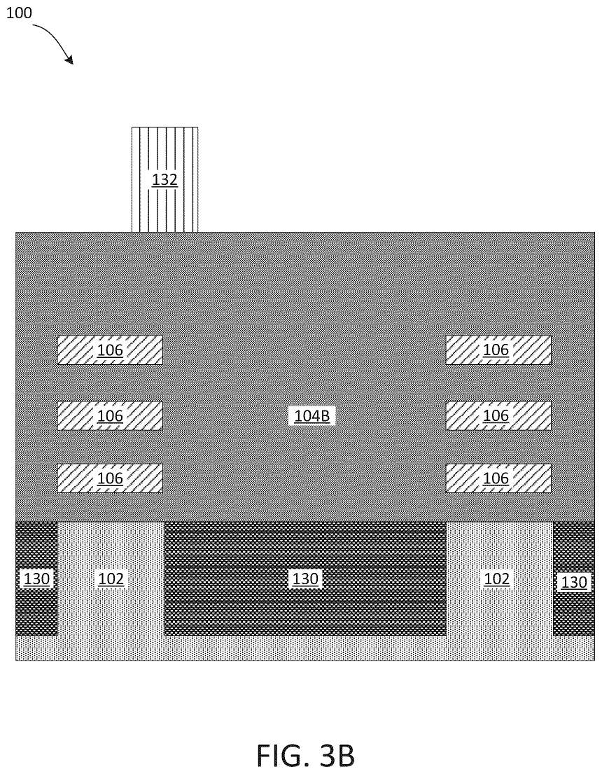

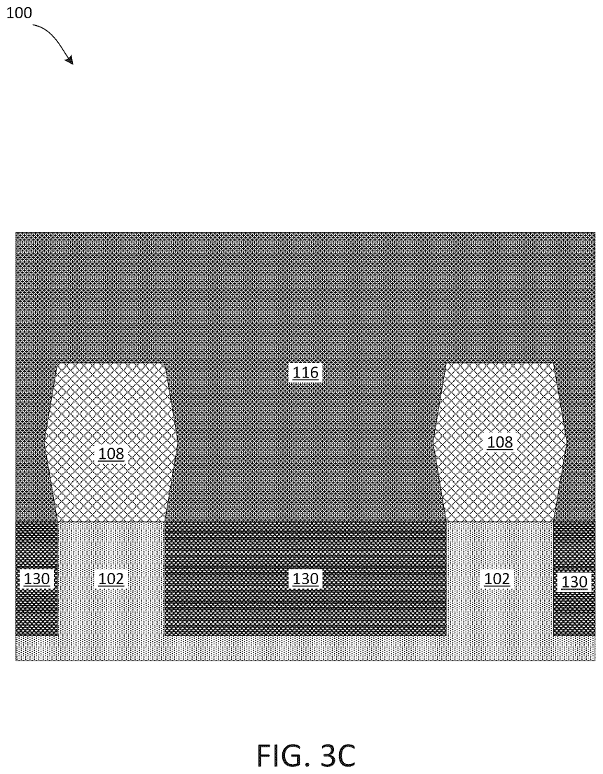

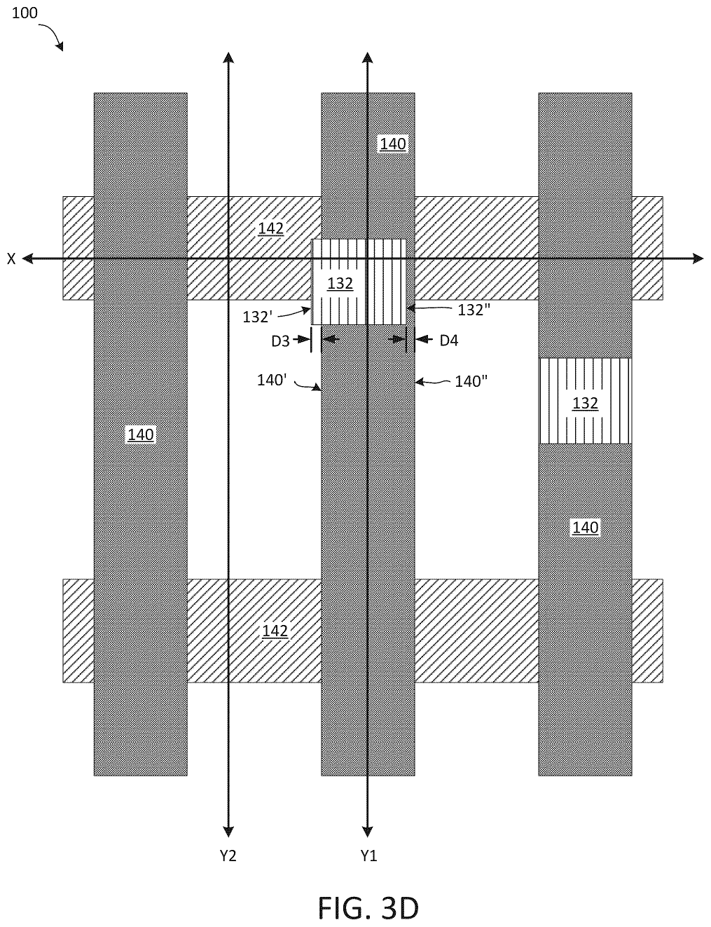

Referring now to FIG. 3A, this figure is a partial cross-sectional view of the semiconductor device of FIG. 2A at a subsequent stage of the fabrication process and taken along the X line of FIG. 3D, according to embodiments. As shown in FIG. 3A, the dummy gate contact layer 132 is patterned so that it at least partially covers the additional gate electrode material 112B, but also so that it does not cover the additional gate electrode material 112A or 112C. The dummy gate contact layer 132 has a first dummy gate contact side 132′ and a second dummy gate contact side 132″. The additional gate electrode material layer 112B below the dummy gate contact layer 132 also has a first gate electrode side 112B′ and a second gate electrode side 112B″. In the example shown in FIG. 3A, there is a slight misalignment between the centers of dummy gate contact layer 132 and the additional gate electrode material layer 112B below the dummy gate contact layer 132. That is, a center of the dummy gate contact layer 132 is offset from the center of the additional gate electrode material layer 112B (or raised gate region). The misalignment is indicated in FIG. 3A as an amount of misalignment D1 on the left side and an amount of misalignment D2 on the right side. Misalignment D1 may be the same or different as misalignment D2. This misalignment is used as an example to show that with very fine pitched device features (e.g., on the nm scale), perfect alignment may not always be achieved. However, although the example shown in FIG. 3A shows an amount of misalignment (D1 and D2), it should be appreciated that in other example embodiments, there may be less of a misalignment or no misalignment at all.

Referring now to FIG. 3B, this figure is a partial cross-sectional view of the semiconductor device of FIG. 2B at a subsequent stage of the fabrication process and taken along the Y1 line of FIG. 3D, according to embodiments. As shown in FIG. 3B, the dummy gate contact layer 132 is patterned.

Referring now to FIG. 3C, this figure is a partial cross-sectional view of the semiconductor device of FIG. 2C at a subsequent stage of the fabrication process and taken along the Y2 line of FIG. 3D, according to embodiments. As shown in FIG. 3C, the dummy gate contact layer 132 is completely removed along this Y2 line.

Referring now to FIG. 3D, this figure is a simplified top view of the semiconductor device shown in FIGS. 3A-3C showing locations of a dummy gate contact, according to embodiments. The dummy gate contact layer 132 shown in FIG. 3D is also shown to have a certain amount of lateral misalignment between the dummy gate contact layer 132 and the gate region 140, as indicated by D3 and D4. The dummy gate contact layer 132 shown in FIG. 3D has a first dummy gate contact side 132′ and a second dummy gate contact side 132″. The gate region 140 also has a first gate region side 140′ and a second gate region side 140″. In certain embodiments, the gate region 140 may include the gate electrode 104 and the additional gate electrode material layer 112. Although the example shown in FIG. 3D shows an amount of misalignment, it should be appreciated that in other example embodiments, there may be less of a misalignment or no misalignment at all.

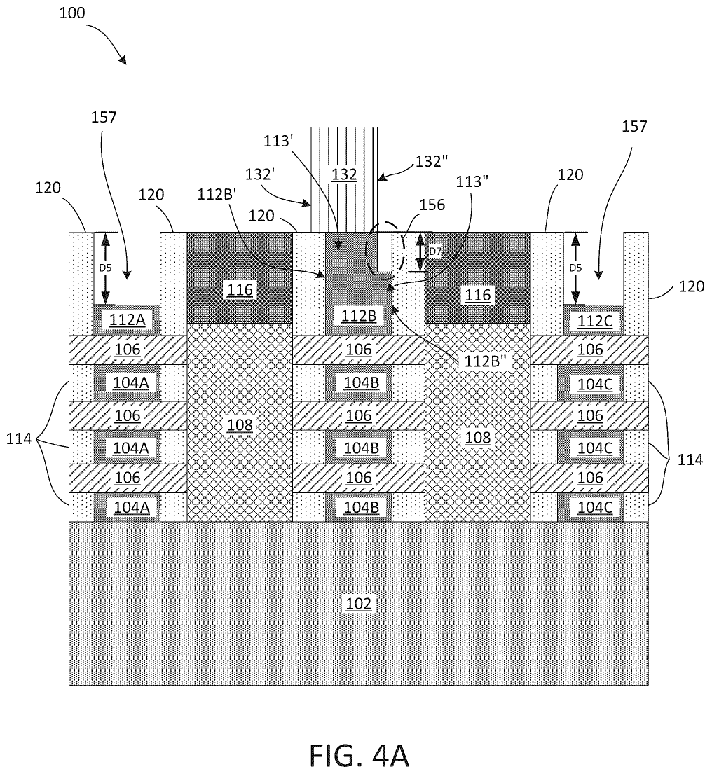

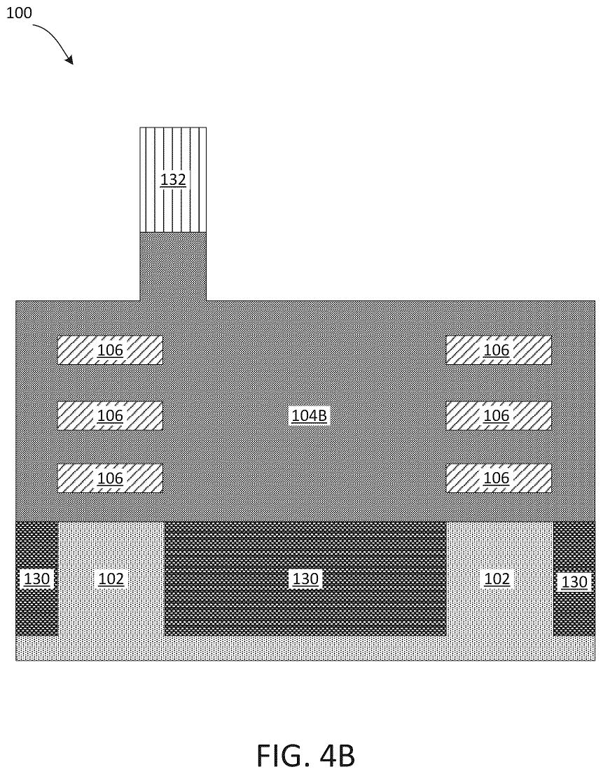

Referring now to 4A, this figure is a partial cross-sectional view of the semiconductor device of FIG. 3A at a subsequent stage of the fabrication process and taken along the X line of FIG. 3D, according to embodiments. As shown in FIG. 4A, a suitable material removal process (e.g., ion beam etching, plasma etching, wet etching, etc.) is used to recess certain portions of the additional gate electrode material layers 112A and 112C (i.e., which is part of the overall gate electrode structure). In certain embodiments, the right and left side additional gate electrode material layer 112A and 112C portions are only recessed partially through this layer to a depth of D5 below the upper surface of the first ILD layer 116 (i.e., to form a recessed gate region). This forms first recesses 157 in these areas. The middle additional gate electrode material layer 112B is at least partially covered by the dummy gate contact layer 132, and is thus at least mostly protected from the material removal process. Therefore, the middle additional gate electrode material layer 112B may be referred to as a raised gate region because it is taller than the right and left additional gate electrode material layers 112A and 112C. Also, the middle additional gate electrode material layer 112B may also have a certain amount of material removed because of any misalignment between the dummy gate contact layer 132 and the additional gate electrode material layer 112B underneath. However, in certain embodiments, because the amount of misalignment (see, FIG. 3A, misalignment D2) may be small, only a small amount of material of the additional gate electrode material layer 112B is removed (e.g., to a depth of D7). This forms a second recess 156 in the area where the middle additional gate electrode material layer 112B was removed. Thus, the second recess 156 is formed in an area above a first raised portion 113″ of the middle additional gate electrode material layer 112B and adjacent to a second raised portion 113′ of the middle additional gate electrode material layer 112B, where the second raised portion 113′ is higher than the first raised portion 113″. It should be appreciated that in a case where there is no misalignment and the dummy gate contact layer 132 covers the entire middle additional gate electrode material layer 112B, there may be no material removed from the middle additional gate electrode material layer 112B in this material removal step.

Referring now to FIG. 4B, this figure is a partial cross-sectional view of the semiconductor device of FIG. 3B at a subsequent stage of the fabrication process and taken along the Y1 line of FIG. 3D, according to embodiments. As shown in FIG. 4B, a suitable material removal process (e.g., ion beam etching, plasma etching, wet etching, etc.) is used to recess certain portions of the gate electrode 104B.

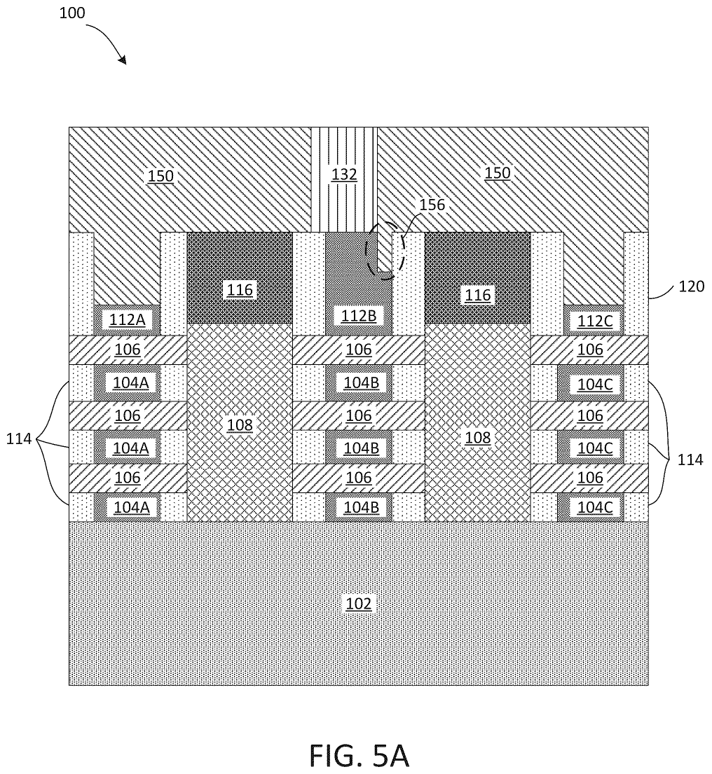

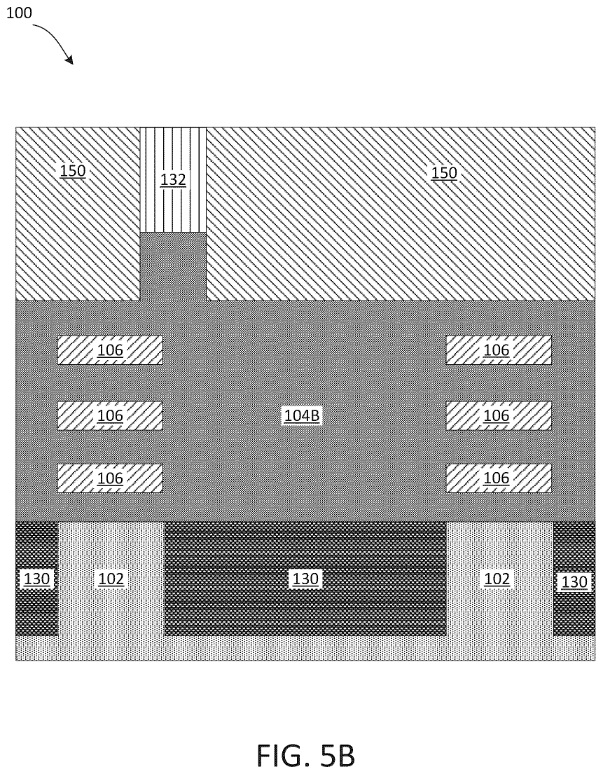

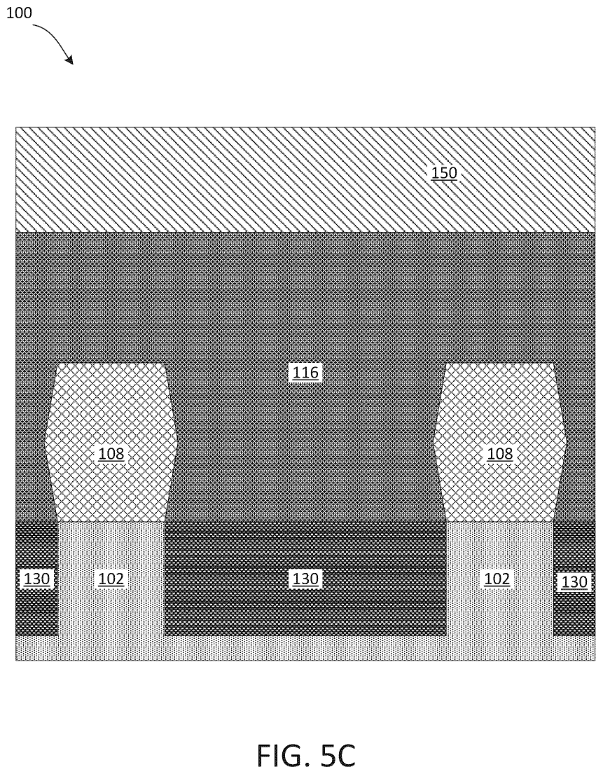

Referring now to FIG. 5A, this figure is a partial cross-sectional view of the semiconductor device of FIG. 4A at a subsequent stage of the fabrication process and taken along the X line of FIG. 3D, according to embodiments. As shown in FIG. 5A, a second ILD layer 150 is formed over the semiconductor device 100, and fills in the first recesses 157 and the second recess 156. An upper surface of the second ILD layer 150 may be coplanar with the upper surface of the dummy gate contact layer 132.

Referring now to FIG. 5B, this figure is a partial cross-sectional view of the semiconductor device of FIG. 4B at a subsequent stage of the fabrication process and taken along the Y1 line of FIG. 3D, according to embodiments. FIG. 5C also shows the formation of the second ILD layer 150.

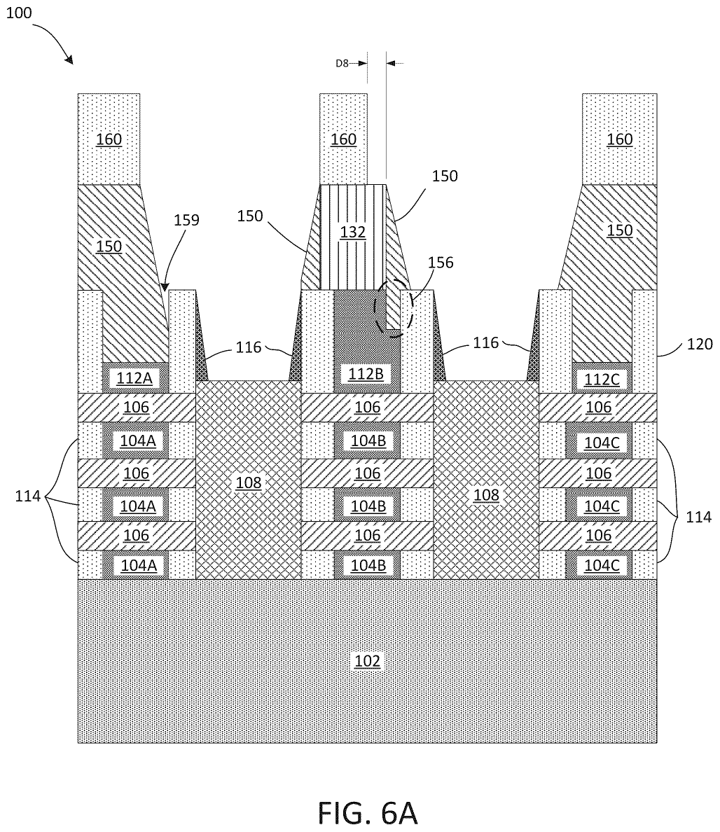

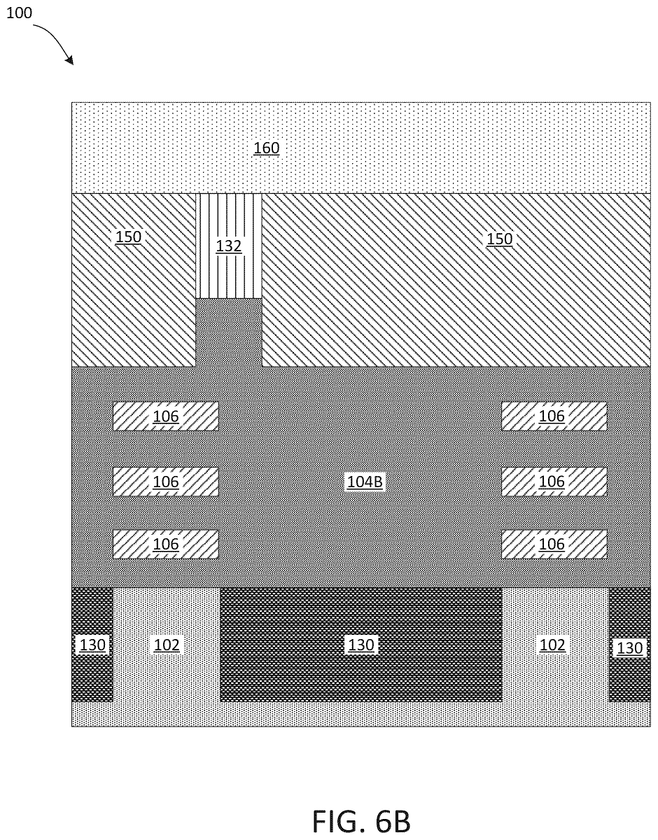

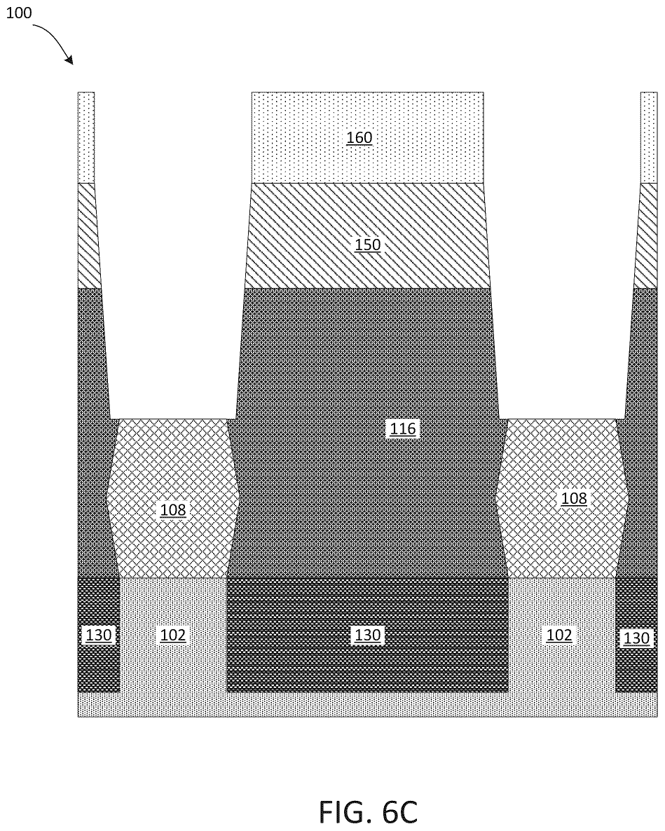

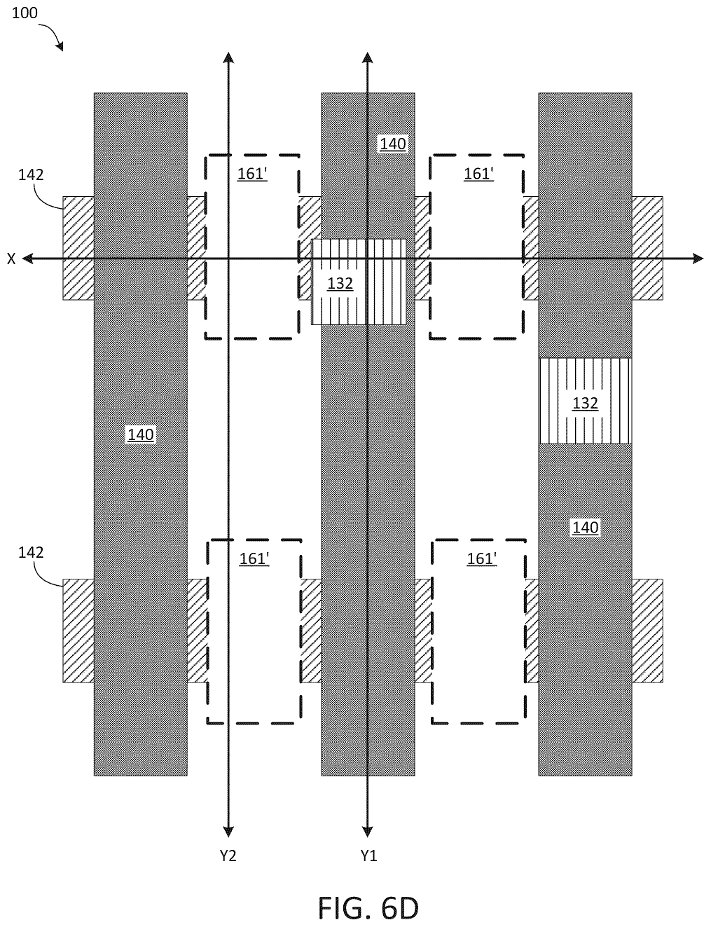

Referring now to FIG. 6A, this figure is a partial cross-sectional view of the semiconductor device of FIG. 5A at a subsequent stage of the fabrication process and taken along the X line of FIG. 6D, according to embodiments. As shown in FIG. 6A, additional manufacturing steps are shown that illustrate the patterning for the subsequent formation of the source/drain contacts (also referred to as CA contacts). An organic planarization (OPL) layer 160 is first formed on top of the second ILD layer 150, and then the OPL layer 160 is patterned to have openings corresponding to the desired locations of the source/drain contacts. Then, any suitable material removal process is performed to remove the portions of the second ILD layer 150 and the first ILD layer 116. In the example shown in FIG. 6A, there may be a certain amount of misalignment D8 between the dummy gate contact layer 132 and the patterned OPL layer 160. This may result in some of the material of the second ILD layer 150 being removed over the left side additional gate electrode material layer 112A in a third recess 159. However, there is still enough insulating material of the second ILD layer 150 to cover the left side additional gate electrode material layer 112A. Moreover, due to the presence of the dummy gate contact layer 132, the reactive ion etching (RIE) process will not attack the material of the second ILD layer 150 that is present in the smaller second recess 156. As mentioned above, it should be appreciated that in other example embodiments, there may be a lesser amount of misalignment of the patterned OPL layer 160, or no misalignment at all. In any event, even if there is a certain amount of misalignment (i.e., with the dummy gate contact layer 132 and/or the OPL layer 160), the presence of the dummy gate contact layer 132 protects any material of the second ILD layer 150 in the second recess 156. As shown in FIG. 6A, the source/drain epitaxial layers 108 are exposed during this material removal step.

Referring now to 6B, this figure is a partial cross-sectional view of the semiconductor device of FIG. 5B at a subsequent stage of the fabrication process and taken along the Y1 line of FIG. 6D, according to embodiments. FIG. 6B also shows the formation of the OPL layer 160.

Referring now to FIG. 6C, this figure is a partial cross-sectional view of the semiconductor device of FIG. 5C at a subsequent stage of the fabrication process and taken along the Y2 line of FIG. 6D, according to embodiments. FIG. 6C also shows the formation of the recesses in the second ILD layer 150 and the first ILD layer 116. As shown in FIG. 6C, the source/drain epitaxial layers 108 are exposed during this material removal step.

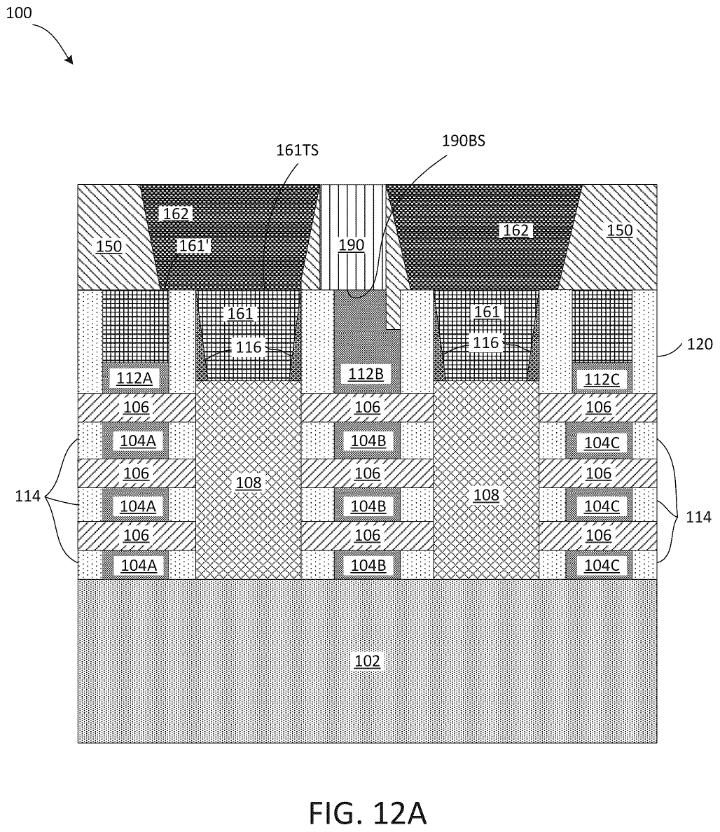

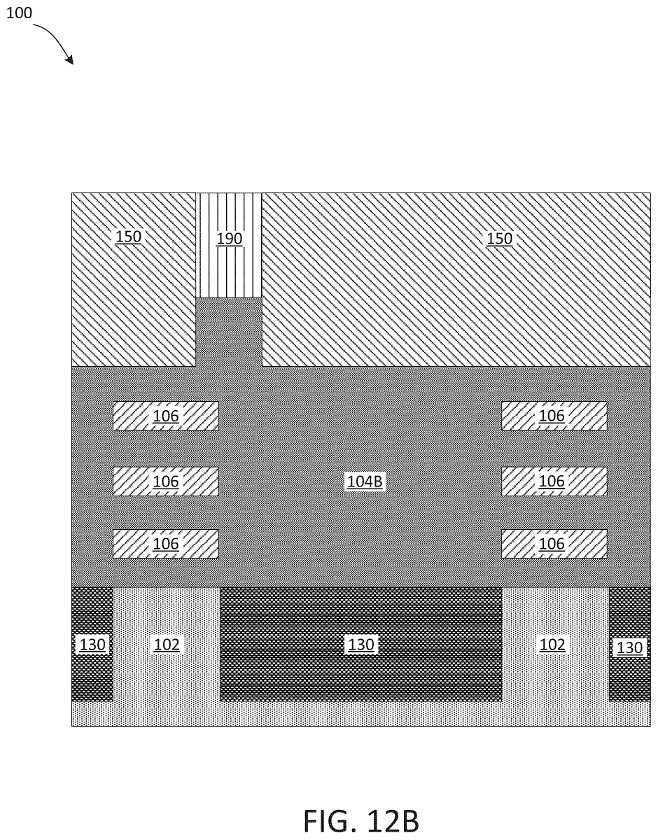

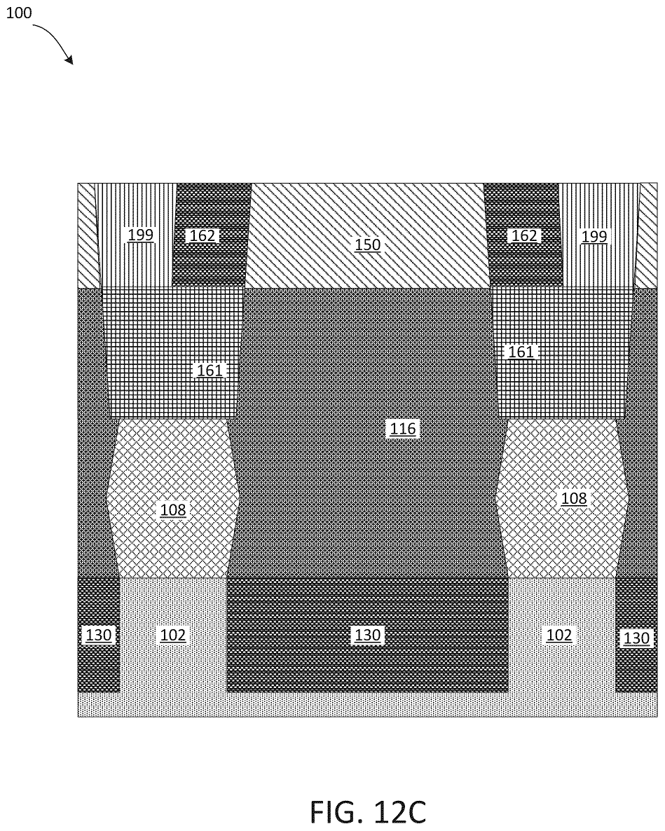

Referring now to FIG. 6D, this figure is a simplified top view of the semiconductor device shown in FIGS. 6A-6C showing source/drain recesses 161′ indicating general locations of where the material was removed to allow for subsequent formation of the source/drain contacts 161 (also referred to as the CA contacts), according to embodiments. The source/drain contacts 161 may also be referred to herein as a CA layer, or a first local interconnect layer. As also shown in FIG. 6D, the dummy gate contact layer 132 is formed at least partially over the active region 142 and the gate regions 140. As will be described in further detail below, the dummy gate contact layer 132 is later removed and gate contacts 190 (see, FIG. 12A) are formed in these general locations. The gate contacts 190 may be referred to herein as a CB layer, or a second local interconnect layer. Of course, multiple CA layers and multiple CB layers may be implemented in the semiconductor device 100 and other local interconnect layers (not shown) may also be implemented. Typically, the CA layer(s) electrically connect to sources or drains while the CB layer(s) electrically connect to gates. However, such typical configuration should certainly not be viewed as limiting. In fact, in some of the embodiments described below, CA layer(s) and/or CB layer(s) may not be connected to sources, drains, or gates.

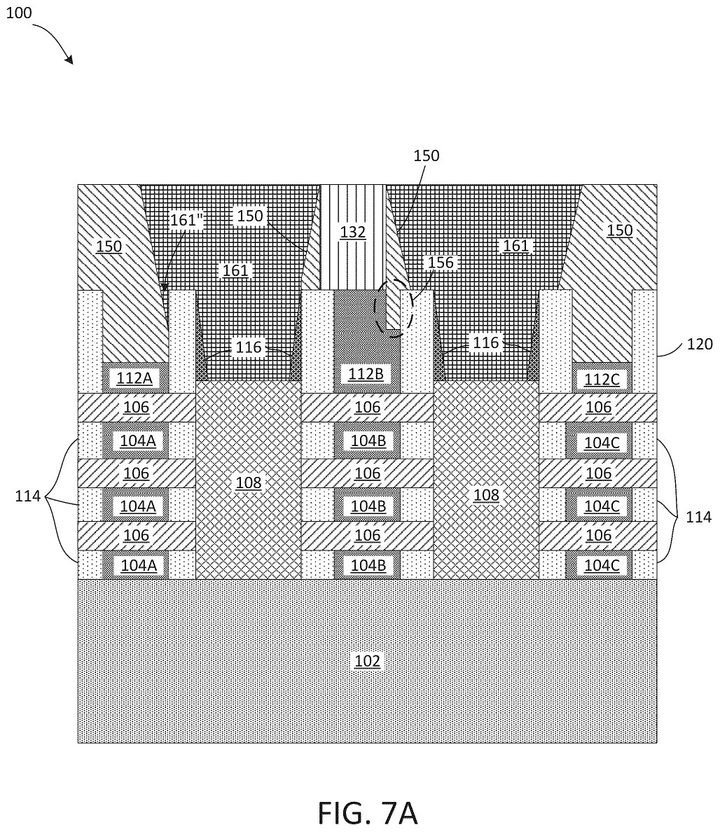

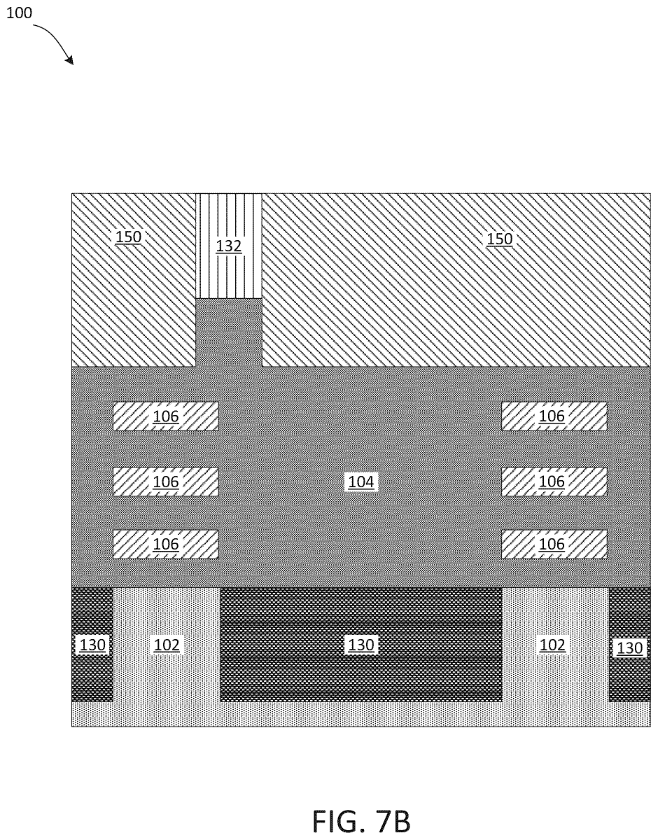

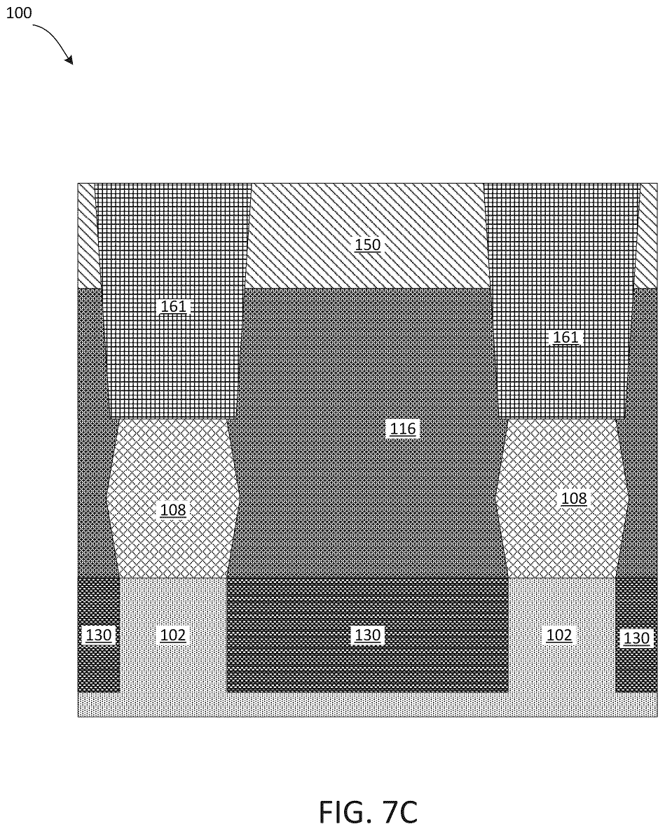

Referring now to FIG. 7A, this figure is a partial cross-sectional view of the semiconductor device of FIG. 6A at a subsequent stage of the fabrication process and taken along the X line of FIG. 6D, according to embodiments. As shown in FIG. 7A, a metallization (or material deposition) process is performed to form the source/drain contacts 161. Then, in certain embodiments, a material removal process such as CMP is performed on the semiconductor device 100 to planarize the upper surfaces of the source/drain contacts 161 and the second ILD layer 152. In certain embodiments, there may be a source/drain contact residual portion 161″ formed in the third recess 159. However, because of the presence of the second ILD layer 150 between the leftmost additional gate electrode material layer 112A and the source/drain contact residual portion 161″ (i.e., that portion of the source/drain contacts 161 formed in the third recess 159), the source/drain residual portion 161″ does not contact the leftmost additional gate electrode material layer 112.

Referring now to FIG. 7B, this figure is a partial cross-sectional view of the semiconductor device of FIG. 6B at a subsequent stage of the fabrication process and taken along the Y1 line of FIG. 6D, according to embodiments. FIG. 7B shows the status of the removal of the OPL layer 160, a metallization (or material deposition) process and the CMP process is performed.

Referring now to FIG. 7C, this figure is a partial cross-sectional view of the semiconductor device of FIG. 6C at a subsequent stage of the fabrication process and taken along the Y2 line of FIG. 6D, according to embodiments. FIG. 7C also shows the locations of the source/drain contacts 161.

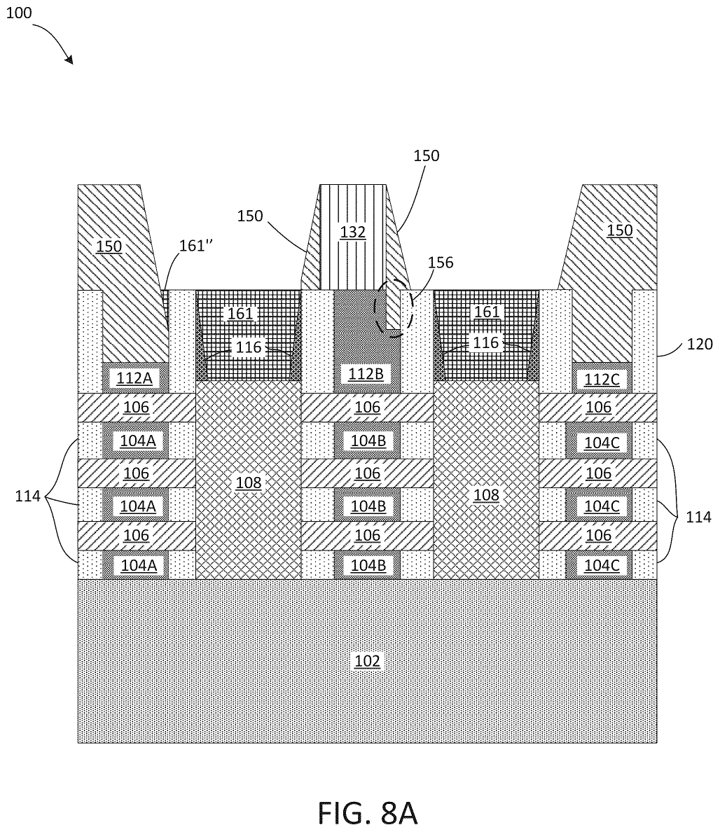

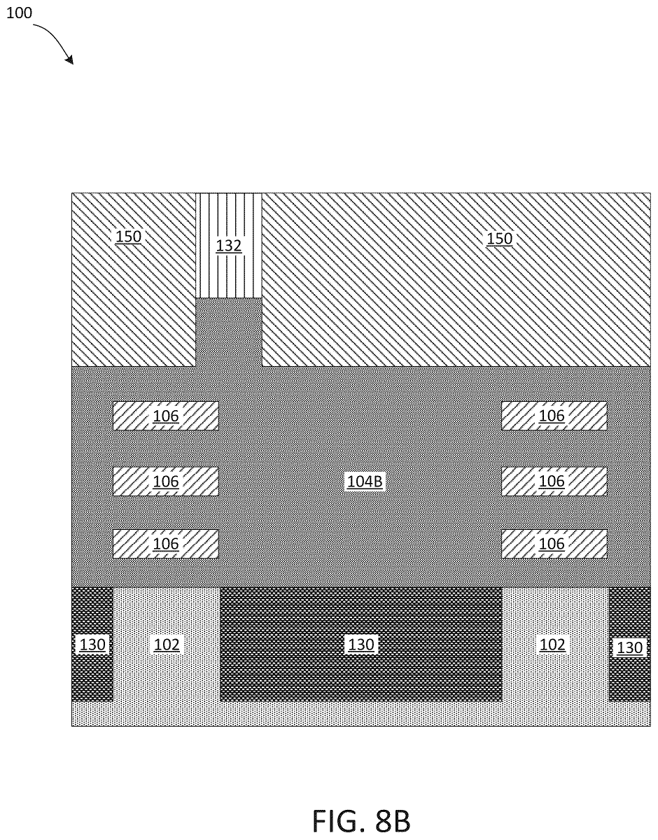

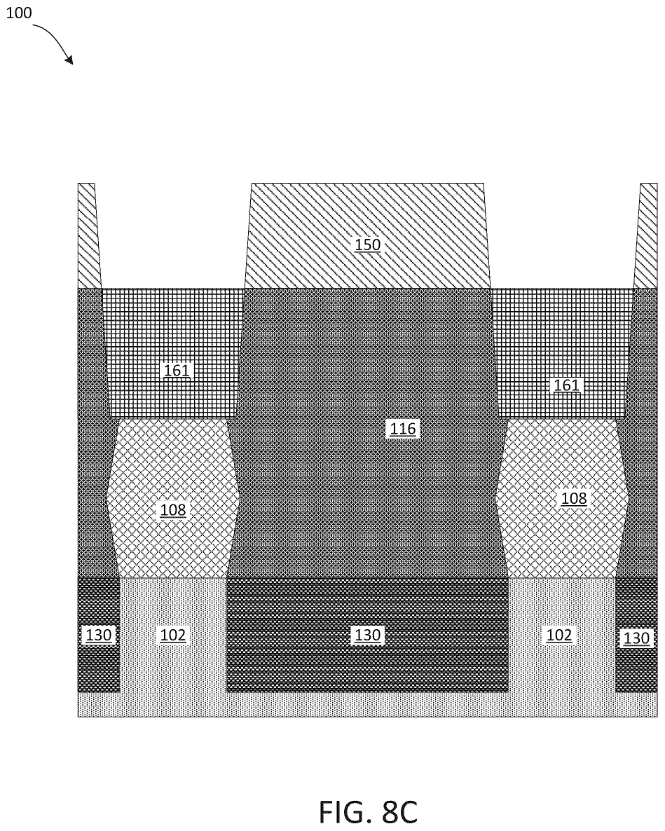

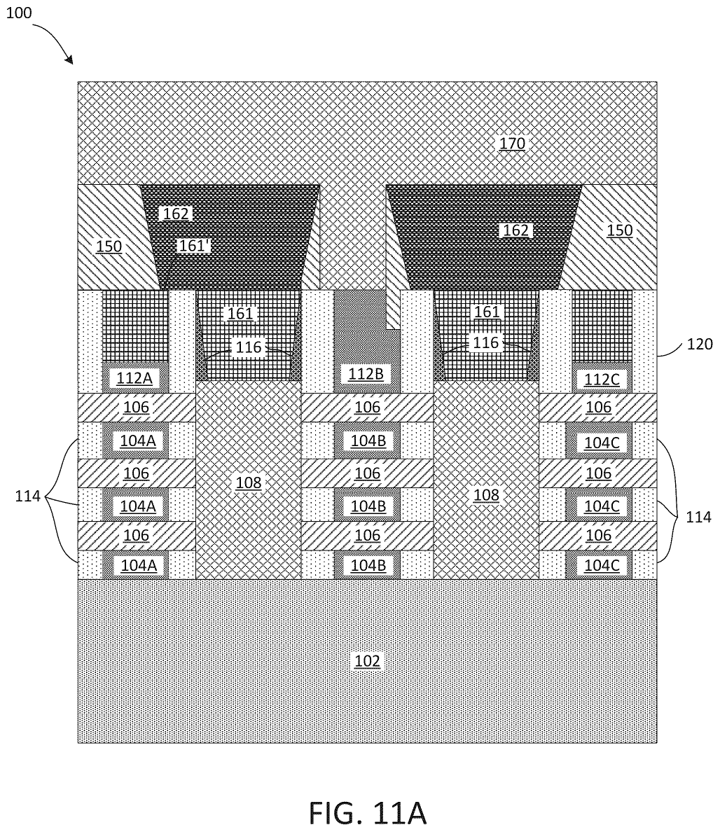

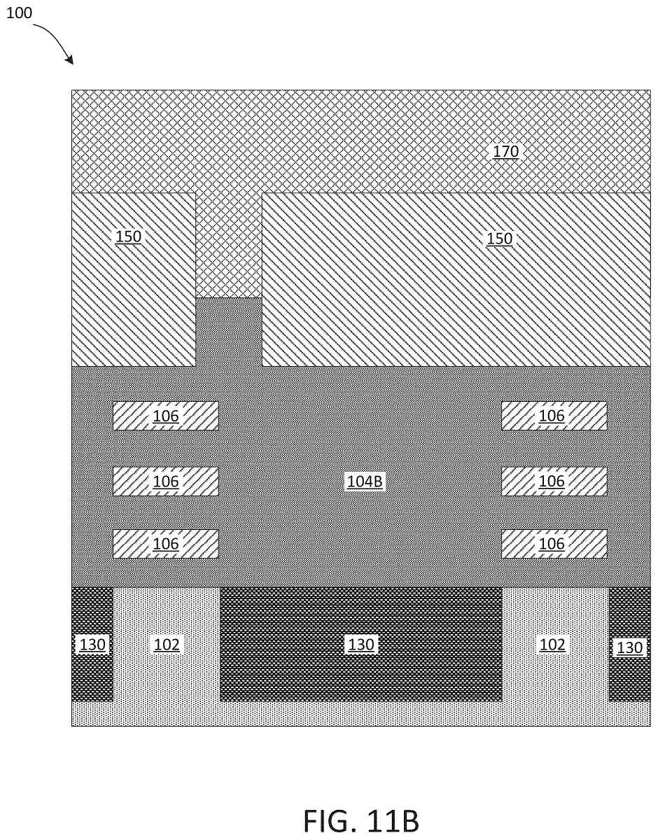

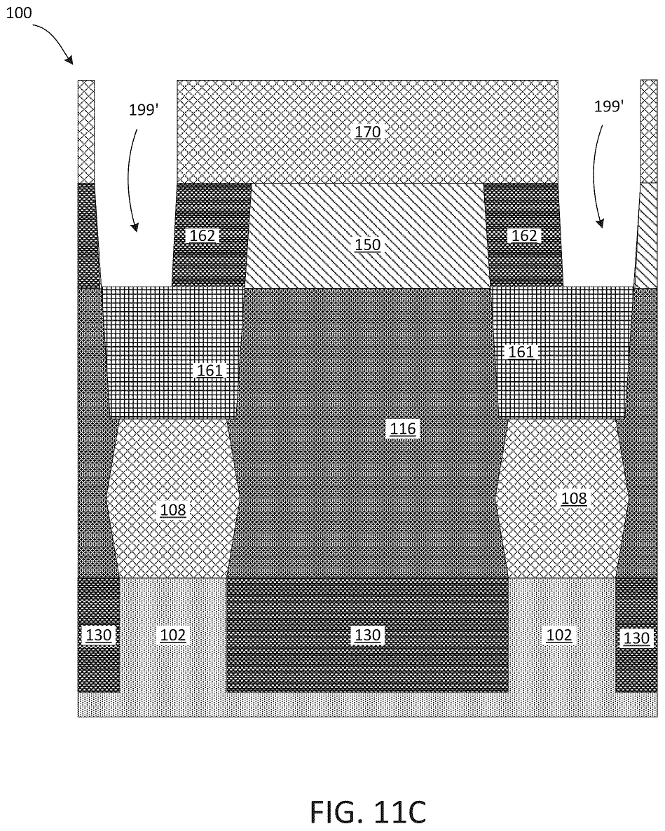

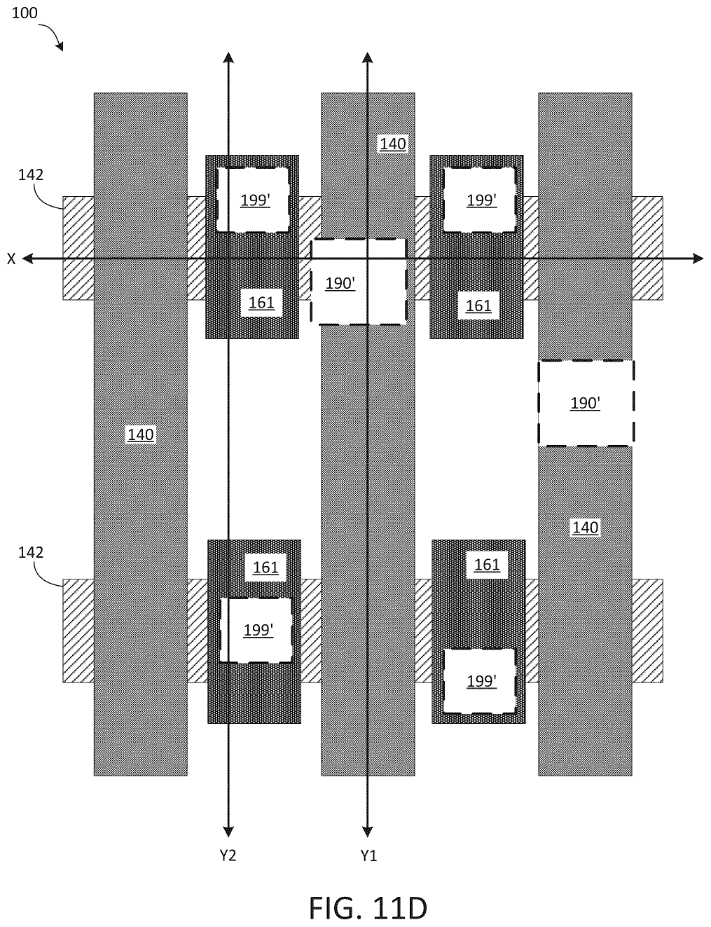

Referring now to FIG. 8A, this figure is a partial cross-sectional view of the semiconductor device of FIG. 7A at a subsequent stage of the fabrication process and taken along the X line of FIG. 6D, according to embodiments. As shown in FIG. 8A, a suitable material removal process is performed to recess the source/drain contacts 161. It should be noted that the source/drain contacts 161 are at a lower level than the dummy gate contact layer 132. Thus, even though there may not be a lot of spacing between the dummy gate contact layer 132 and the source/drain contacts 161 when viewed in plan view (e.g., FIG. 11D), because the middle additional gate electrode material layer 112B was not recessed due to the presence of the dummy gate contact layer 132, the gate electrode contacts 190 will be formed at a higher level (when viewed in cross-section) than the source/drain contacts 161. This may help to reduce or eliminate the chances of electrical shorting between the source/drain contacts 161 and the gate contacts 190. As also shown in FIG. 8A, in the example where there is a certain amount of misalignment in the process, there may be a small source/drain contact residual portion 161″ of the source/drain contact 161 metal material in the area next to the second ILD layer 150.

Referring now to FIG. 8B, this figure is a partial cross-sectional view of the semiconductor device of FIG. 7B at a subsequent stage of the fabrication process and taken along the Y1 line of FIG. 6D, according to embodiments. FIG. 8B appears the same as FIG. 7B.

Referring now to FIG. 8C, this figure is a partial cross-sectional view of the semiconductor device of FIG. 7C at a subsequent stage of the fabrication process and taken along the Y2 line of FIG. 6D, according to embodiments. FIG. 8C also shows recessing of the source/drain contacts 161.

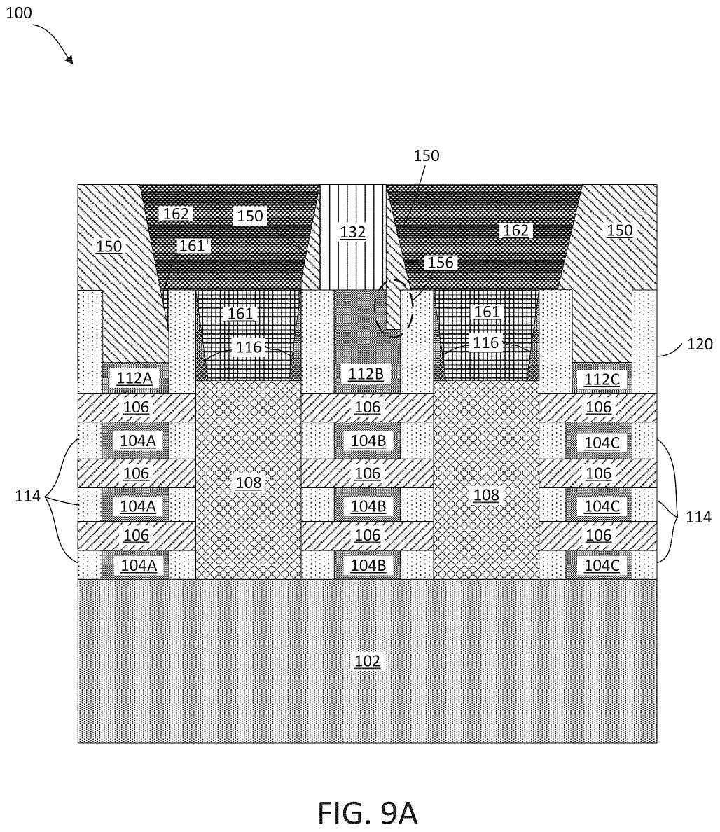

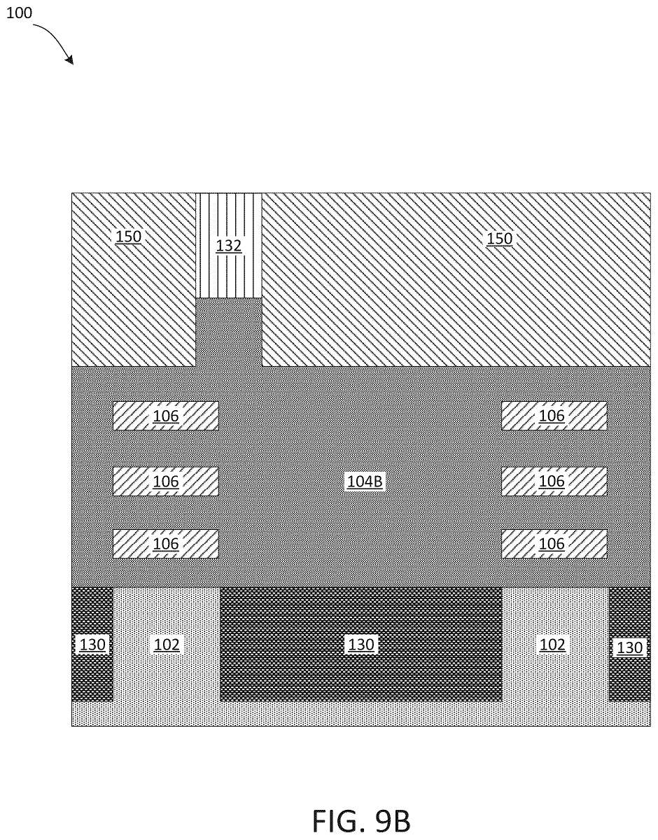

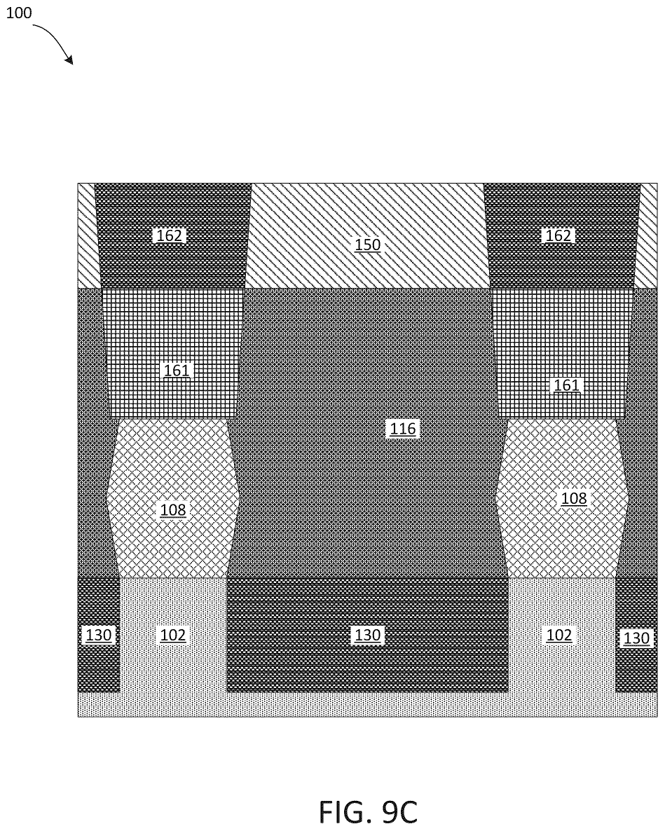

Referring now to FIG. 9A, this figure is a partial cross-sectional view of the semiconductor device of FIG. 8A at a subsequent stage of the fabrication process and taken along the X line of FIG. 6D, according to embodiments. As shown in FIG. 9A, a third ILD layer 162 is formed in the areas where the source/drain contacts 161 were recessed. In certain embodiments, a suitable material removal process, such as CMP, may be performed to planarize the upper surface of the semiconductor device 100.

Referring now to FIG. 9B, this figure is a partial cross-sectional view of the semiconductor device of FIG. 8B at a subsequent stage of the fabrication process and taken along the Y1 line of FIG. 6D, according to embodiments. FIG. 9B appears the same as FIG. 8B.

Referring now to FIG. 9C, this figure is a partial cross-sectional view of the semiconductor device of FIG. 8C at a subsequent stage of the fabrication process and taken along the Y2 line of FIG. 6D, according to embodiments. FIG. 9C also shows the formation of the third ILD layer 162.

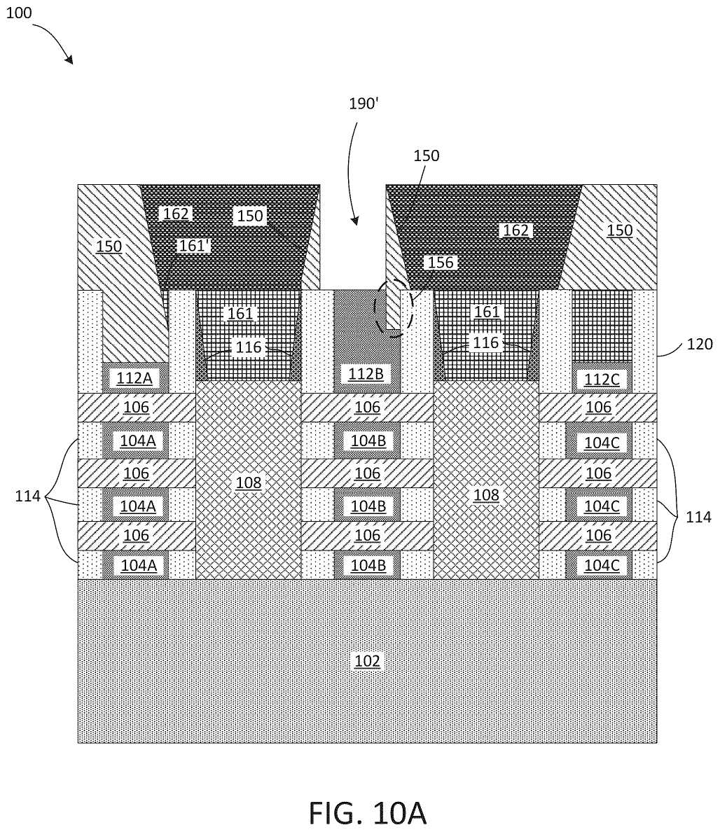

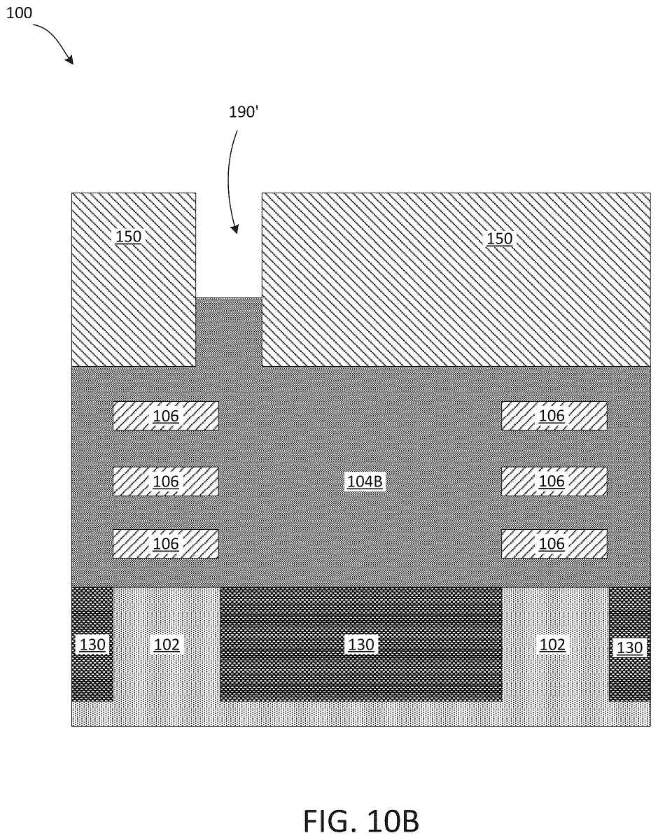

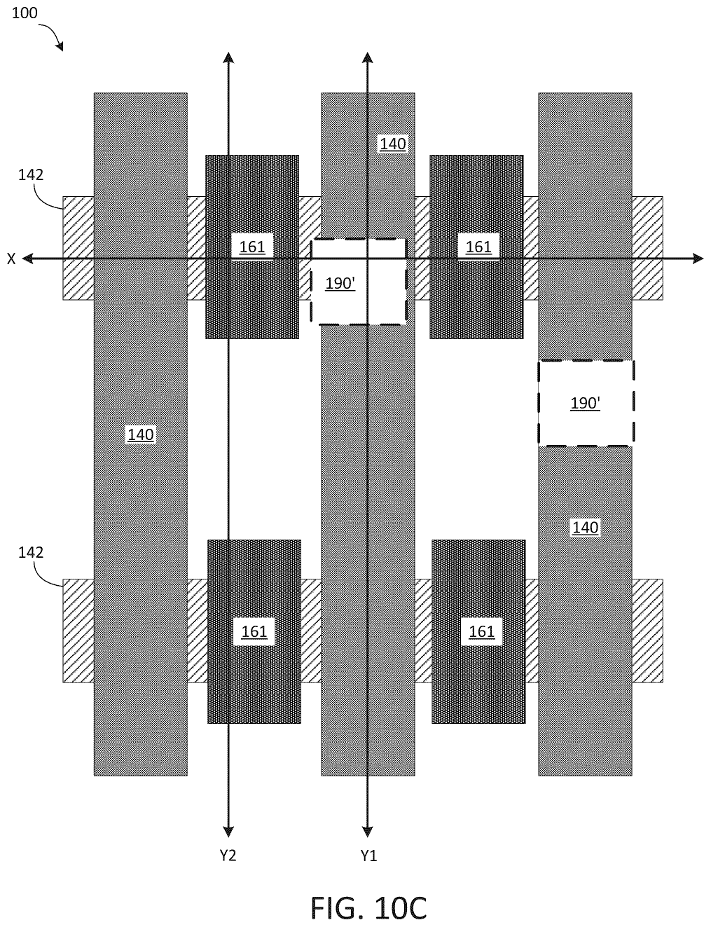

Referring now to FIG. 10A, this figure is a partial cross-sectional view of the semiconductor device of FIG. 9A at a subsequent stage of the fabrication process and taken along the X line of FIG. 10C, according to embodiments. As shown in FIG. 10A, a suitable material removal process is performed to selectively remove the dummy gate contact layer 132 and create a gate contact recess 190′.

Referring now to FIG. 10B, this figure is a partial cross-sectional view of the semiconductor device of FIG. 9B at a subsequent stage of the fabrication process and taken along the Y1 line of FIG. 10C, according to embodiments. FIG. 10B also shows the location of the gate contact recess 190′.

Referring now to FIG. 10C, this figure is a simplified top view of the semiconductor device shown in FIGS. 10A-10B showing locations where the dummy gate contacts have been removed, according to embodiments. FIG. 10C also shows the location of the contact recesses 190′.

Referring now to FIG. 11A, this figure is a partial cross-sectional view of the semiconductor device of FIG. 10A at a subsequent stage of the fabrication process and taken along the X line of FIG. 11D, according to embodiments. As shown in FIG. 11A, a second OPL layer 170 may be formed and patterned so that additional VA contact patterning can be performed in a subsequent processing step. A VA contact, in general, is a conductive metal contact that may be used to apply a voltage to the semiconductor device 100.

Referring now to FIG. 11B, this figure is a partial cross-sectional view of the semiconductor device of FIG. 10B at a subsequent stage of the fabrication process and taken along the Y1 line of FIG. 11D, according to embodiments. FIG. 11B also shows the formation of the second OPL layer 170.

Referring now to FIG. 11C, this figure is a partial cross-sectional view of the semiconductor device of FIG. 9C at a subsequent stage of the fabrication process and taken along the Y2 line of FIG. 11D, according to embodiments. As shown in FIG. 11C, VA contact recesses 199′ are formed through the third ILD layer 162 to expose the upper surfaces of the source/drain contacts 161.

Referring now to FIG. 11D, this figure is a simplified top view of the semiconductor device shown in FIGS. 11A-11C showing locations additional contact patterning, according to embodiments. Although the VA contact recesses are not present in the cross-sectional views of FIGS. 11A and 11B, FIG. 11D shows the locations of the VA contact recesses 199′ in plan view. It should be appreciated that the locations, number and combination of the VA contact recesses 199′ are merely one example, and other configurations are contemplated to be within the scope of the present embodiments.

Referring now to FIG. 12A, this figure is a partial cross-sectional view of the semiconductor device of FIG. 11A at a subsequent stage of the fabrication process and taken along the X line of FIG. 11D, according to embodiments. As shown in FIG. 12A, a second OPL layer 170 ash process followed by a metallization is performed in the gate contact recess 190′ to form the gate contact 190. In certain embodiments, the center of the gate contact 190 is offset from a center of the additional gate electrode material layer 112B (or raised gate region). Thus, even though there may not be a lot of spacing between the gate contact 190 and the source/drain contacts 161 when viewed in plan view (e.g., FIG. 11D), because the middle additional gate electrode material layer 112B was not recessed due to the presence of the dummy gate contact layer 132, the gate electrode contact 190 is formed at a higher level (when viewed in cross-section) than the source/drain contacts 161. In other words, in certain embodiments, a top surface 161TS of the source/drain contacts 161 is at or below a bottom surface 190BS of the gate contact 190. This may help to reduce or eliminate the chances of electrical shorting between the source/drain contacts 161 and the gate contacts 190.

Referring now to FIG. 12B, this figure is a partial cross-sectional view of the semiconductor device of FIG. 11B at a subsequent stage of the fabrication process and taken along the Y1 line of FIG. 11D, according to embodiments. FIG. 12B also shows the formation of the gate contacts 190.

Referring now to FIG. 12C, this figure is a partial cross-sectional view of the semiconductor device of FIG. 11C at a subsequent stage of the fabrication process and taken along the Y2 line of FIG. 11D, according to embodiments. FIG. 12C also shows the formation of the VA contacts 199 in the locations where the VA recesses 199′ were located, as shown in FIG. 11C.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
an active region;
a first gate electrode;
a second gate electrode having a height that is less than a height of the first gate electrode; and
a gate contact formed on the first gate electrode and overlapping with the active region.

2. The semiconductor device of claim 1, further comprising a source/drain epitaxial layer.

3. The semiconductor device of claim 2, further comprising a source/drain contact formed on the source/drain epitaxial layer.

4. The semiconductor device of claim 3, wherein a top surface of the source/drain contact is at or below a bottom surface of the gate contact.

5. The semiconductor device of claim 3, further comprising a source/drain contact residual portion formed over the second gate contact.

6. The semiconductor device of claim 1, wherein a center of the gate contact is offset from a center of the first gate electrode.

7. The semiconductor device of claim 1, wherein the first gate electrode includes a first raised portion and a second raised portion, the second raised portion having a greater height than the first raised portion.

8. The semiconductor device of claim 7, wherein a recess is formed in an area above the first raised portion and adjacent to the second raised portion.

9. The semiconductor device of claim 8, further comprising an interlayer dielectric (ILD) layer formed over the second gate electrode.

10. The semiconductor device according to claim 9, wherein the ILD layer is also formed in the recess.

11. The semiconductor device according to claim 10, wherein the gate contact is formed over the second raised portion of the first gate electrode, but is not formed over the first raised portion of the first gate electrode.

12. The semiconductor device according to claim 1, further comprising:
a source/drain epitaxial layer;
a source/drain contact formed on the source/drain epitaxial layer; and
a gate spacer formed on sides of the source/drain contact.

13. The semiconductor device according to claim 12, further comprising a source/drain contact residual portion formed over the second gate electrode, wherein the source/drain contact residual portion is electrically isolated from the source/drain contact by the gate spacer.

14. The semiconductor device according to claim 1, wherein the first gate electrode and the second gate electrode are formed as a nanosheet stack structure including alternating layers of a semiconductor layer and a high-x metal gate layer.

15. A method of manufacturing a semiconductor device, the method comprising:
forming an active region;
forming a first gate electrode;
forming a second gate electrode having a height that is less than a height of the first gate electrode; and
forming a gate contact on the first gate electrode and overlapping with the active region.

16. The method of claim 15, further comprising forming a source/drain epitaxial layer.

17. The method of claim 16, further comprising forming a source/drain contact on the source/drain epitaxial layer.

18. The method of claim 17, wherein a top surface of the source/drain contact is at or below a bottom surface of the gate contact.

19. The method of claim 17, further comprising forming a source/drain contact residual portion over the second gate contact.

20. The method of claim 15, wherein the first gate electrode includes a first raised portion and a second raised portion, the second raised portion having a greater height than the first raised portion.
